(19) United States
(12) Patent Application Publication
(10) Pub. No.: US 2022/0269172 A1
(43) Pub. Date: Aug. 25, 2022

(54) RADIATION-SENSITIVE RESIN COMPOSITION, METHOD OF FORMING RESIST PATTERN, AND POLYMER

(71) Applicant: JSR CORPORATION, Tokyo (JP)

(72) Inventors: Katsuaki NISHIKORI, Tokyo (JP); Kazuya KIRIYAMA, Tokyo (JP); Takuhiro TANIGUCHI, Tokyo (JP); Ken MARUYAMA, Tokyo (JP)

(73) Assignee: JSR CORPORATION, Tokyo (JP)

(21) Appl. No.: 17/673,952

(22) Filed: Feb. 17, 2022

(30) Foreign Application Priority Data
Feb. 22, 2021 (JP) 2021-026687
Oct. 29, 2021 (JP) 2021-178257

(51) Int. Cl. G03F 7/039; G03F 7/004; C08F 220/18; C08F 220/22

(52) U.S. Cl. CPC G03F 7/039; G03F 7/0045; C08F 220/1806; C08F 220/1807; C08F 220/1808; C08F 220/1804; C08F 220/1809; C08F 220/1812; C08F 220/1811; C08F 220/22

(57) ABSTRACT

Provided are: a radiation-sensitive resin composition, a method of forming a resist pattern, and a polymer which enable forming a resist pattern with favorable sensitivity to exposure light and superiority in terms of CDU performance and resolution. The radiation-sensitive resin composition contains: a polymer having: a first structural unit represented by formula (1), and a second structural unit derived from a (meth)acrylic acid ester including an acid-labile group; and a radiation-sensitive acid generator.

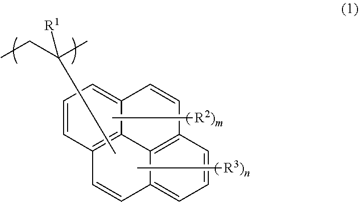

### CROSS-REFERENCE TO RELATED APPLICATIONS

The present application claims priority to Japanese Patent Application No. 2021-26687, filed Feb. 22, 2021 and to Japanese Patent Application No. 2021-178257, filed Oct. 29, 2021. The contents of these applications are incorporated herein by reference in their entirety.

### BACKGROUND OF THE INVENTION

### Field of the Invention

The present invention relates to a radiation-sensitive resin composition, a method of forming a resist pattern, and a polymer.

### Discussion of the Background

A radiation-sensitive resin composition for use in microfabrication by lithography generates an acid at light-exposed regions upon an irradiation with a radioactive ray, e.g., an electromagnetic wave such as a far ultraviolet ray such as an ArF excimer laser beam (wavelength of 193 nm), a KrF excimer laser beam (wavelength of 248 nm), etc. or an extreme ultraviolet ray (EUV) (wavelength of 13.5 nm), or a charged particle ray such as an electron beam. A chemical reaction in which the acid serves as a catalyst causes a difference between the light-exposed regions and light-unexposed regions in rates of dissolution in a developer solution, whereby a resist pattern is formed on a substrate.

Such a radiation-sensitive resin composition is required not only to have favorable sensitivity to exposure light such as an extreme ultraviolet ray and an electron beam, but also to have superiority in terms of CDU (Critical Dimension Uniformity) performance, resolution, and the like.

Types, molecular structures, and the like of polymers, acid generating agents, and other components which may be used in radiation-sensitive resin compositions have been investigated to meet these requirements, and combinations thereof have been further investigated in detail (see Japanese Unexamined Patent Applications, Publication Nos. 2010-134279, 2014-224984, and 2016-047815).

### SUMMARY OF THE INVENTION

According to one aspect of the present invention, a radiation-sensitive resin composition contains: a polymer having: a first structural unit represented by formula (1);

and a second structural unit derived from a (meth)acrylic acid ester including an acid-labile group; and a radiation-sensitive acid generator.

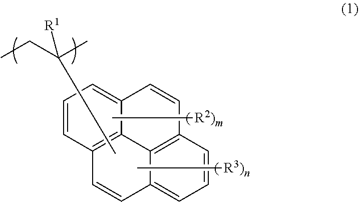

In the formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.

According to another aspect of the present invention, a method of forming a resist pattern includes: applying a radiation-sensitive resin composition directly or indirectly on a substrate; exposing a resist film formed by the applying; and developing the resist film exposed. The radiation-sensitive resin composition contains: a polymer having: a first structural unit represented by formula (1); and a second structural unit derived from a (meth)acrylic acid ester including an acid-labile group; and a radiation-sensitive acid generator.

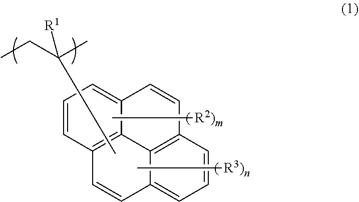

In the formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.

According to still another aspect of the present invention, a polymer has: a first structural unit represented by formula (1); and a second structural unit derived from a (meth)acrylic acid ester including an acid-labile group.

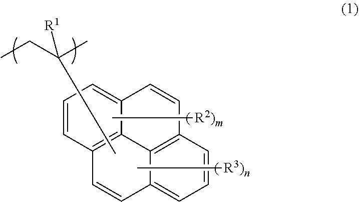

In the formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.

### DESCRIPTION OF THE EMBODIMENTS

Along with the further microfabrication of resist patterns, required levels for the aforementioned types of performance are further elevated, and the conventional radiation-sensitive resin composition described above is not capable of meeting these requirements.

One embodiment of the invention made for solving the aforementioned problems is a radiation-sensitive resin composition containing: a polymer (hereinafter, may be also referred to as “(A) polymer” or “polymer (A)”) having a first structural unit represented by the following formula (1), and a second structural unit derived from a (meth)acrylic acid ester including an acid-labile group; and a radiation-sensitive acid generator (hereinafter, may be also referred to as “(B) acid generator” or “acid generator (B)”),

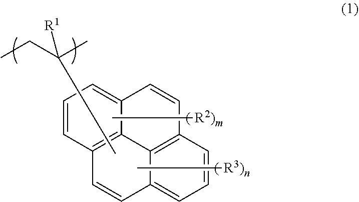

wherein, in the above formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.

An other embodiment of the invention made for solving the aforementioned problems is a method of forming a resist pattern, the method including applying a radiation-sensitive resin composition directly or indirectly on a substrate; exposing a resist film formed by the applying; and developing the resist film exposed.

Still another embodiment of the invention made for solving the aforementioned problems is a polymer (hereinafter, may be also referred to as “(A) polymer” or “polymer (A)”) having a first structural unit represented by the above formula (1); and a second structural unit derived from a (meth)acrylic acid ester including an acid-labile group.

The radiation-sensitive resin composition and the method of forming a resist pattern of the embodiments of the present invention enable a resist pattern to be formed with favorable sensitivity to exposure light and superiority in terms of the CDU performance and the resolution. The polymer of the still another embodiment of the present invention can be suitably used as a component of the radiation-sensitive resin composition of the one embodiment of the present invention. Therefore, these can be suitably used in working processes for semiconductor devices, and the like, in which further progress of miniaturization is expected in the future.

Hereinafter, the radiation-sensitive resin composition, the method of forming a resist pattern, and the polymer of the embodiments of the present invention will be described in detail.

### Radiation-Sensitive Resin Composition

The radiation-sensitive composition of the one embodiment of the present invention contains the polymer (A) and the acid generator (B). The radiation-sensitive resin composition typically contains an organic solvent (hereinafter, may be also referred to as “(D) organic solvent” or “organic solvent (D)”). The radiation-sensitive composition may contain, as a favorable component, an acid diffusion control agent (hereinafter, may be also referred to as “(C) acid diffusion control agent” or “acid diffusion control agent (C)”). The radiation-sensitive resin composition may contain, within a range not leading to impairment of the effects of the present invention, other optional component(s).

Due to the polymer (A) and the acid generator (B) being contained, the radiation-sensitive composition enables a resist pattern to be formed with favorable sensitive to exposure light and superiority in terms of the CDU performance and the resolution. Although not necessarily clarified and without wishing to be bound by any theory, the reason for achieving the aforementioned effects by the radiation-sensitive resin composition due to involving such a constitution may be presumed, for example, as in the following. It is believed that due to the polymer (A) having the first structural unit represented by the following formula (1), described below, an amount of acid generated from the acid generator (B), etc. upon exposure increases. Furthermore, it is considered that an acid-labile group is dissociated from the second structural unit by an action of the acid generated from the acid generator (B), etc., and a carboxy group derived from (meth)acrylic acid, which is highly soluble in a developer solution, is generated. Thus, it is believed that, in conjunction with the amount of acid generated from the acid generator (B), etc. increasing, an amount of the acid-labile group which is dissociated from the second structural unit increases, whereby the amount of the carboxy group derived from the (meth)acrylic acid increases. It is considered that as a result, a resist pattern is enabled to be formed with favorable sensitivity to exposure light and superiority in terms of the CDU performance and the resolution.

The radiation-sensitive composition may be prepared by, for example: mixing the polymer (A) and the acid generator (B), and the acid diffusion control agent (C), the organic solvent (D), and the other optional component(s), which is/are added as needed, in a predetermined ratio, and preferably filtering a thus resulting mixture through a membrane filter having a pore size of no greater than 0.2 μm.

Each component contained in the radiation-sensitive resin composition is described below.

### (A) Polymer

The polymer (A) has the first structural unit (hereinafter, may be also referred to as “structural unit (I)”) represented by the following formula (1), described later, and the second structural unit (hereinafter, may be also referred to as “structural unit (II)”) derived from the (meth)acrylic acid ester including an acid-labile group. The radiation-sensitive resin composition may contain one, or two or more types of the polymer (A).

The polymer (A) preferably further has a structural unit (hereinafter, may be also referred to as “structural unit (III)”) including a phenolic hydroxyl group. The polymer (A) may further have another structural unit (hereinafter, may be also referred to as simply “other structural unit”) aside from the structural units (I) to (III).

The lower limit of a proportion of the polymer (A) in the radiation-sensitive resin composition with respect to total components other than the organic solvent (D) contained in the radiation-sensitive resin composition is preferably 50% by mass, more preferably 70% by mass, and still more preferably 80% by mass. The upper limit of the proportion is preferably 99% by mass, and more preferably 95% by mass.

The lower limit of a polystyrene equivalent weight average molecular weight (Mw) of the polymer (A) as determined by gel permeation chromatography (GPC) is preferably 1,000, more preferably 3,000, still more preferably 5,000, further preferably 6,000, and particularly preferably 5,500. The upper limit of the Mw is preferably 50,000, more preferably 30,000, still more preferably 15,000, further preferably 10,000, and particularly preferably 8,000. When the Mw of the polymer (A) falls within the above range, coating characteristics of the radiation-sensitive resin composition can be improved.

The upper limit of a ratio (hereinafter, may be also referred to as “dispersity index” or “Mw/Mn”) of the Mw with respect to a polystyrene-equivalent number average molecular weight (Mn) of the polymer (A) as determined by GPC is preferably 2.5, more preferably 2.0, and still more preferably 1.7. The lower limit of the ratio is typically 1.0, and is preferably 1.1, more preferably 1.2, and still more preferably 1.3.

Method of Determining Mw and Mn

As referred to herein, the Mw and Mn of the polymer (A) are values measured by gel permeation chromatography (GPC) under the following conditions.

GPC columns: “G2000 HXL”×2, “G3000 HXL”×1, and “G4000 HXL”×1, available from Tosoh Corporation

column temperature: 40° C.

elution solvent: tetrahydrofuran

flow rate: 1.0 mL/min

sample concentration: 1.0% by mass

amount of injected sample: 100 uL

detector: differential refractometer

standard substance: mono-dispersed polystyrene

The polymer (A) can be synthesized by, for example, polymerizing a monomer that gives each structural unit according to a well-known procedure.

Each structural unit contained in the polymer (A) is described below.

Structural Unit (I)

The structural unit (I) is a structural unit represented by the following formula (I). Due to the polymer (A) having the structural unit (I), a resist pattern can be formed with favorable sensitivity to exposure light and superiority in terms of the CDU performance and the resolution. The polymer (A) may have one, or two or more types of the structural unit (I).

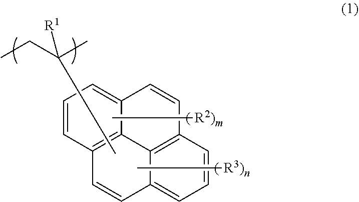

In the formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.

Examples of the halogen atom which may be represented by R¹, R², or R³ include a fluorine atom, a chlorine atom, a bromine atom, and an iodine atom.

The number of “carbon atoms” as referred to herein means the number of carbon atoms constituting a group, and the “organic group” as referred to herein means a group having at least one carbon atom.

The monovalent organic group having 1 to 20 carbon atoms which may be represented by R¹, R², or R³ is exemplified by: a monovalent hydrocarbon group having 1 to 20 carbon atoms; a group (α) that includes a divalent hetero atom-containing group between two adjacent carbon atoms of the monovalent hydrocarbon group having 1 to 20 atoms; a group (β) obtained by substituting with a monovalent hetero atom-containing group, a part or all of hydrogen atoms included in the monovalent hydrocarbon group having 1 to 20 atoms or the group (α); a group (γ) obtained by combining the monovalent hydrocarbon group having 1 to 20 atoms, the group (α), or the group (β) with a divalent hetero atom-containing group; and the like.

The “hydrocarbon group” as referred to herein may be exemplified by a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not including a ring structure but being constituted with only a chain structure, and may be exemplified by both a linear hydrocarbon group and a branched chain hydrocarbon group. The “alicyclic hydrocarbon group” as referred to herein means a hydrocarbon group that includes, as a ring structure, not an aromatic ring structure but an alicyclic structure alone, and may be exemplified by both a monocyclic alicyclic hydrocarbon group and a polycyclic alicyclic hydrocarbon group. With regard to this, it is not necessary for the alicyclic hydrocarbon group to be constituted with only an alicyclic structure; it may include a chain structure in a part thereof. The “aromatic hydrocarbon group” as referred to herein means a hydrocarbon group that includes an aromatic ring structure as a ring structure. With regard to this, it is not necessary for the aromatic hydrocarbon group to be constituted with only an aromatic ring structure; it may include a chain structure or an alicyclic structure in a part thereof.

The monovalent hydrocarbon group having 1 to 20 carbon atoms is exemplified by a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and the like.

Examples of the monovalent chain hydrocarbon group having 1 to 20 carbon atoms include: alkyl groups such as a methyl group, an ethyl group, an n-propyl group, and an i-propyl group; alkenyl groups such as an ethenyl group, a propenyl group, and a butenyl group; alkynyl groups such as an ethynyl group, a propynyl group, and a butynyl group; and the like.

Examples of the monovalent alicyclic hydrocarbon group having 3 to 20 carbon atoms include: alicyclic saturated hydrocarbon groups such as a cyclopentyl group, a cyclohexyl group, a norbornyl group, an adamantyl group, a tricyclodecyl group, and a tetracyclododecyl group; alicyclic unsaturated hydrocarbon groups such as a cyclopentenyl group, a cyclohexenyl group, a norbornenyl group, a tricyclodecenyl group, and a tetracyclododecenyl group; and the like.

Examples of the monovalent aromatic hydrocarbon group having 6 to 20 carbon atoms include: aryl groups such as a phenyl group, a tolyl group, a xylyl group, a naphthyl group, and an anthryl group; aralkyl groups such as a benzyl group, a phenethyl group, a naphthylmethyl group, and an anthrylmethyl group; and the like.

The hetero atom that may constitute the monovalent or divalent hetero atom-containing group is exemplified by an oxygen atom, a nitrogen atom, a sulfur atom, a phosphorus atom, a silicon atom, a halogen atom and the like. Examples of the halogen atom include a fluorine atom, a chlorine atom, a bromine atom, and an iodine atom.

Examples of the divalent hetero atom-containing group include —O—, —CO—, —S—, —CS—, —NR′—, groups obtained by combining at least two of the aforementioned groups (e.g., —O—CO— and the like), and the like, wherein R′ represents a hydrogen atom or a monovalent hydrocarbon group.

In light of copolymerizability of a monomer that gives the structural unit (I), R¹ represents preferably a hydrogen atom.

m is preferably 0 to 2, more preferably 0 or 1, and still more preferably 0. n is preferably 0 to 2, more preferably 0 or 1, and still more preferably 0. Of these, m and n both being 0 is particularly preferred.

The lower limit of a proportion of the structural unit (I) in the polymer (A) with respect to total structural units constituting the polymer (A) is preferably 0.5 mol %, more preferably 1 mol %, still more preferably 2.5 mol %, and further preferably 5 mol %. The upper limit of the proportion is preferably 40 mol %, more preferably 30 mol %, still more preferably 20 mol %, and further preferably 15 mol %. When the proportion of the structural unit (I) falls within the above range, the sensitivity to exposure light, and the CDU performance and the resolution resulting from the radiation-sensitive resin composition can be further improved.

Structural Unit (II)

The structural unit (II) is a structural unit derived from a (meth)acrylic acid ester including an acid-labile group. The “acid-labile group” as referred to herein means a group that substitutes for a hydrogen atom in a carboxy group, and is dissociated by an action of an acid to give a carboxy group. The “(meth)acrylic acid ester” is a concept that encompasses both an acrylic acid ester and a methacrylic acid ester. The acid-labile group is dissociated by an action of the acid generated from the acid generator (B), etc. upon exposure, whereby the solubility of the polymer (A) in the developer solution is changed between the light-exposed regions and the light-unexposed regions, and thus a resist pattern can be formed. The polymer (A) may contain one, or two or more types of the structural unit (II).

Examples of the structural unit (II) include structural units (hereinafter, may be also referred to as “structural units (II-1) to (II-3)”) represented by the following formulae (2-1) to (2-3), and the like. It is to be noted that for example, in the following formula (2-1), —C (R^{X}) (R^{Y}) (R^{Z}), which bonds to an ethereal oxygen atom derived from the carboxy group, corresponds to the acid-labile group.

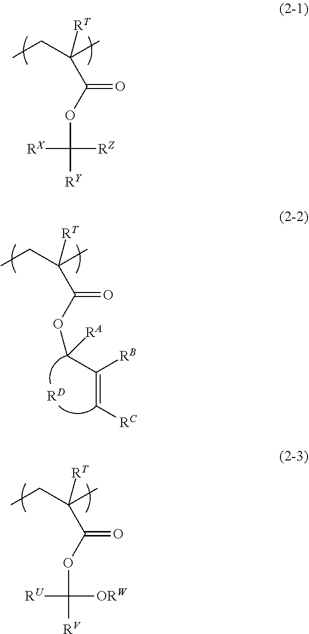

In the above formula (2-1), the above formula (2-2), and the above formula (2-3), each R^{T} independently represents a hydrogen atom, a fluorine atom, a methyl group, or a trifluoromethyl group.

In the above formula (2-1), each 10 independently represents a monovalent hydrocarbon group having 1 to 20 carbon atoms; and R^{Y} and R^{Z} each independently represent a substituted or unsubstituted monovalent hydrocarbon group having 1 to 20 carbon atoms, or R^{Y} and R^{Z} taken together represent a saturated alicyclic structure having 3 to 20 ring atoms together with the carbon atom to which R^{Y} and R^{Z} bond.

In the above formula (2-2), R^{A} represents a hydrogen atom; R^{B} and R^{C} each independently represent a hydrogen atom or a monovalent hydrocarbon group having 1 to 20 carbon atoms; and R^{D} represents a divalent hydrocarbon group having 1 to 20 carbon atoms which constitutes an unsaturated alicyclic structure having 4 to 20 ring atoms together with the carbon atoms to which R^{A}, R^{B}, and R^{C} bond, respectively.

In the above formula (2-3), R^{U} and R^{V} each independently represent a hydrogen atom or a monovalent hydrocarbon group having 1 to 20 carbon atoms, and each R^{W} independently represents a monovalent hydrocarbon group having 1 to 20 carbon atoms, or R^{U} and R^{V} taken together represent an alicyclic structure having 3 to 20 ring atoms, together with the carbon atom to which R^{U} and R^{V} bond, or R^{U} and R^{W} taken together represent an aliphatic heterocyclic structure having 4 to 20 ring atoms, together with the carbon atom to which R^{U} bonds and the oxygen atom to which R^{W} bonds.

The number of “ring atoms” as referred to herein means the number of atoms constituting a ring structure, and in the case of a polycyclic ring structure, the number of “ring atoms” means the number of atoms constituting the polycyclic ring.

Examples of the monovalent hydrocarbon group having 1 to 20 carbon atoms which may be represented by R^{X}, R^{Y}, R^{Z}, R^{B}, R^{C}, R^{U}, R^{V}, or R^{W} include, of the monovalent organic groups having 1 to 20 carbon atoms which may be represented by R¹, R², or R³ in the formula (1), described above, groups similar to the groups exemplified as the monovalent hydrocarbon group having 1 to 20 carbon atoms, and the like.

Examples of the substituent which may be included in the hydrocarbon group represented by R^{Y} or R^{Z} include: a halogen atom such as a fluorine atom, a hydroxy group, a carboxy group, a cyano group, a nitro group, an alkoxy group, an alkoxycarbonyl group, an alkoxycarbonyloxy group, an acyl group, an acyloxy group, and the like. Of these, a halogen atom is preferred, and a fluorine atom is more preferred.

Examples of the saturated alicyclic structure having 3 to 20 ring atoms which may be constituted by R^{Y} and R^{Z} taken together, together with the carbon atom to which R^{Y} and R^{Z} bond, include monocyclic saturated alicyclic structures such as a cyclopropane structure, a cyclobutane structure, a cyclopentane structure, and a cyclohexane structure; polycyclic saturated alicyclic structures such as a norbornane structure and an adamantane structure; and the like.

Examples of the divalent hydrocarbon group having 1 to 20 carbon atoms represented by R^{D} include, of the monovalent organic groups having 1 to 20 carbon atoms which may be represented by R¹, R², or R³ in the formula (1), described above, groups obtained by removing one hydrogen atom from each of the groups exemplified as the monovalent hydrocarbon group having 1 to 20 carbon atoms.

Examples of the unsaturated alicyclic structure having 4 to 20 ring atoms which is constituted by R^{D}, together with the carbon atoms to which R^{A}, R^{B}, and R^{C} bond, respectively include monocyclic unsaturated alicyclic structures such as a cyclobutene structure, a cyclopentene structure, a cyclohexene structure; polycyclic unsaturated alicyclic structures such as a norbornene structure; and the like.

Examples of the alicyclic structure having 3 to 20 ring atoms which may be represented by R^{U} and R^{V} taken together, together with the carbon atom to which R^{U} and R^{V} bond, include: monocyclic saturated alicyclic structures such as a cyclopropane structure, a cyclobutane structure, a cyclopentane structure, and a cyclohexane structure; polycyclic saturated alicyclic structures such as a norbornane structure and an adamantane structure; monocyclic unsaturated alicyclic structures such as a cyclopropene structure, a cyclobutene structure, a cyclopentene structure, and a cyclohexene structure; polycyclic unsaturated alicyclic structures such as a norbornene structure; and the like.

Examples of the aliphatic heterocyclic structure having 4 to 20 ring atoms which may be represented by R^{U} and R^{W} taken together, together with the carbon atom to which R^{U} bonds and the oxygen atom to which R^{W} bonds, include: saturated oxygen-containing heterocyclic structures such as an oxacyclobutane structure, an oxacyclopentane structure, and an oxacyclohexane structure; unsaturated oxygen-containing heterocyclic structures such as an oxacyclobutene structure, an oxacyclopentene structure, and an oxacyclohexene structure; and the like.

In light of copolymerizability of a monomer that gives the structural unit (II), R^{T} represents preferably a hydrogen atom or a methyl group.

R^{X} represents preferably the chain hydrocarbon group or the aromatic hydrocarbon group, more preferably the alkyl group or the aryl group, and still more preferably a methyl group, an ethyl group, an i-propyl group, or a phenyl group.

R^{Y} and R^{Z} each represent preferably a substituted or unsubstituted chain hydrocarbon group or a substituted or unsubstituted alicyclic hydrocarbon group, more preferably an unsubstituted chain hydrocarbon group or a substituted alicyclic hydrocarbon group, still more preferably an unsubstituted alkyl group or a substituted cycloalkyl group, and further preferably a methyl group, or a cyclohexyl group substituted with a fluorine atom.

Furthermore, R^{Y} and R^{Z} taken together preferably represent a saturated alicyclic structure having 3 to 20 ring atoms, together with the carbon atom to which R^{Y} and R^{Z} bond.

The saturated alicyclic structure is preferably a cyclopentane structure, a cyclohexane structure, or an adamantane structure.

R^{B} represents preferably a hydrogen atom.

R^{C} represents preferably a hydrogen atom or the chain hydrocarbon group, more preferably a hydrogen atom or an alkyl group, and still more preferably a hydrogen atom or a methyl group.

The unsaturated alicyclic structure having 4 to 20 ring atoms constituted by R^{D}, together with the carbon atoms to which R^{A}, R^{B}, and R^{C} bond, respectively, is preferably a monocyclic unsaturated alicyclic structure, and more preferably a cyclohexene structure.

The structural unit (II) is preferably the structural unit (II-1) or the structural unit (II-2).

The structural unit (II-1) is, for example, preferably one of structural units (hereinafter, may be also referred to as “structural units (II-1-1) to (II-1-8)”) represented by the following formulae (2-1-1) to (2-1-8).

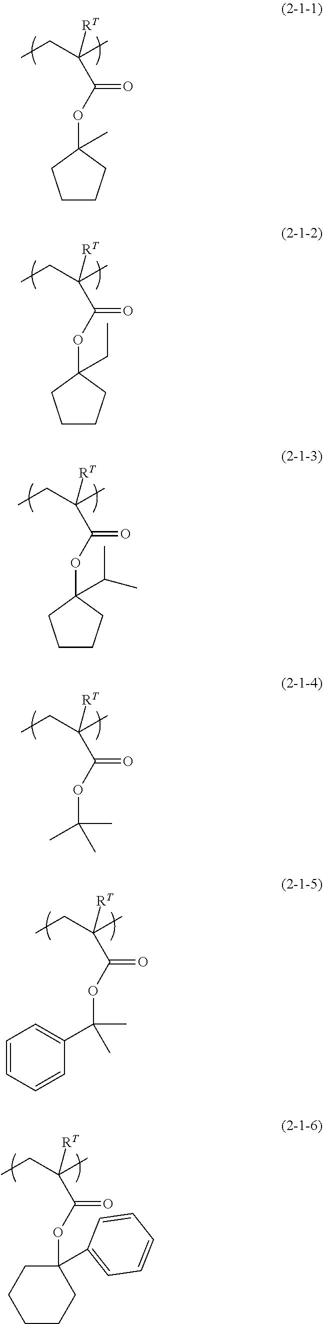

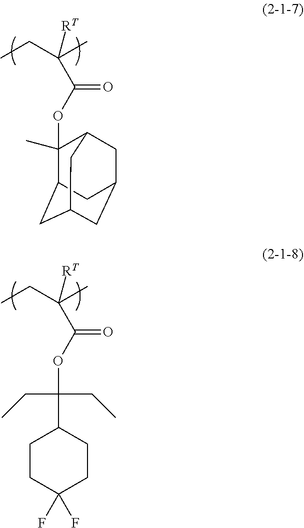

In the above formulae (2-1-1) to (2-1-8), R^{T} is as defined in the above formula (2-1).

The structural unit (II-2) is preferably a structural unit (hereinafter, may be also referred to as “structural unit (II-2-1)”) represented by the following formula (2-2-1).

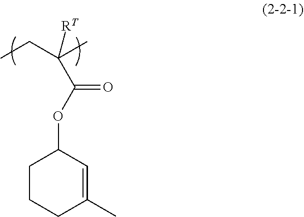

In the above formula (2-2-1), R^{T} is as defined in the above formula (2-2).

The lower limit of a proportion of the structural unit (II) in the polymer (A) with respect to total structural units constituting the polymer (A) is preferably 30 mol %, more preferably 40 mol %, and still more preferably 50 mol %. The upper limit of the proportion is preferably 90 mol %, more preferably 80 mol %, and still more preferably 70 mol %. When the proportion of the structural limit (II) falls within the above range, the sensitivity to exposure light, and the CDU performance and the resolution resulting from the radiation-sensitive resin composition can be further improved.

Structural Unit (III)

The structural unit (III) is a structural unit including a phenolic hydroxyl group. The “phenolic hydroxyl group” as referred to herein is not limited to a hydroxy group directly bonding to a benzene ring, and means any hydroxy group directly bonding to an aromatic ring in general. The polymer (A) may include one, or two or more types of the structural unit (III).

In a case of exposure to KrF, exposure to EUV, or exposure to an electron beam, when the polymer (A) has the structural unit (III), the sensitivity of the radiation-sensitive resin composition to exposure light can be further improved. Thus, in the case of the polymer (A) having the structural unit (III), the radiation-sensitive resin composition can be suitably used as a radiation-sensitive resin composition for exposure to KrF, exposure to EUV, or exposure to an electron beam.

Examples of the structural unit (III) include structural units (hereinafter, may be also referred to as “structural units (III-1) to (III-16)”) represented by the following formulae (3-1) to (3-16), and the like.

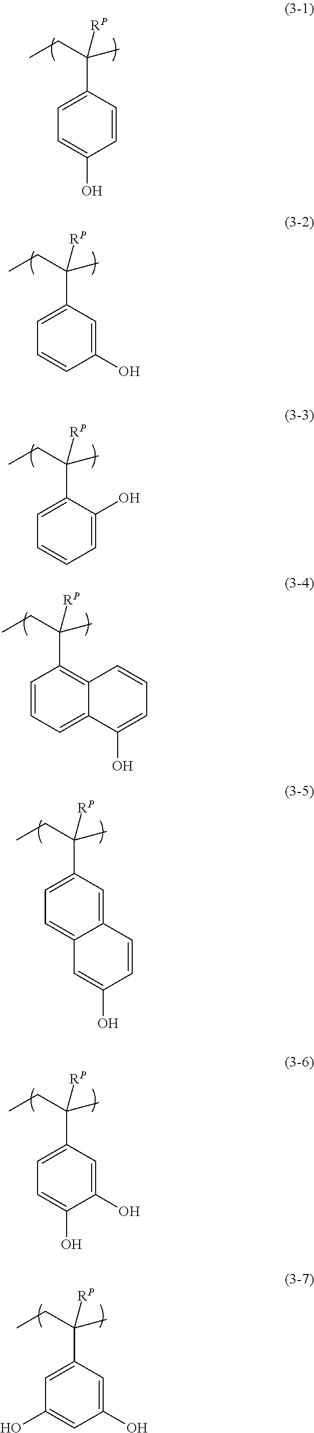

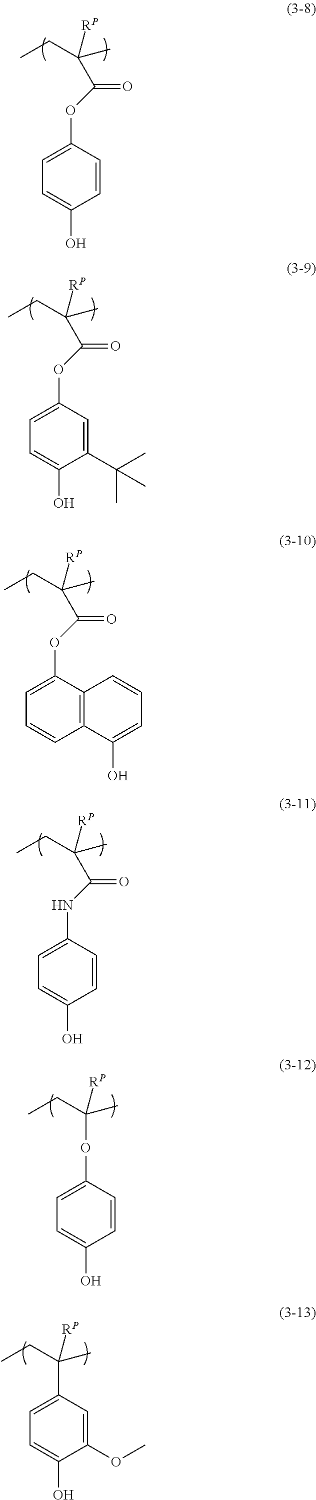

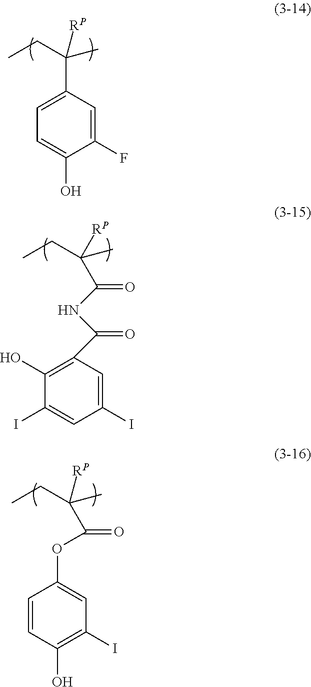

In the above formulae (3-1) to (3-16), R^{P} represents a hydrogen atom, a fluorine atom, a methyl group, or a trifluoromethyl group.

In light of copolymerizability of a monomer that gives the structural unit (III), R^{P} represents preferably a hydrogen atom or a methyl group, and more preferably a hydrogen atom.

The structural unit (III) is preferably the structural unit (III-1), the structural unit (III-2), the structural unit (III-3), the structural unit (III-6), the structural unit (III-15), the structural unit (III-16), or a combination thereof. In the case of the structural unit being the combination, the CDU performance and the resolution resulting from the radiation-sensitive resin composition can be further improved. The combination is preferably a combination of the structural unit (III-1) with the structural unit (III-2), the structural unit (III-3), the structural unit (III-6), the structural unit (III-15), or the structural unit (III-16).

In the case of the polymer (A) having the structural unit (III), the lower limit of a proportion of the structural unit (III) in the polymer (A) with respect to total structural units constituting the polymer (A) is preferably 5 mol %, more preferably 10 mol %, still more preferably 20 mol %, and particularly preferably 25 mol %. The upper limit of the proportion is preferably 60 mol %, more preferably 50 mol %, still more preferably 40 mol %, and particularly preferably 35 mol %.

As the monomer that gives the structural unit (III), for example, a monomer obtained by substituting a hydrogen atom in the phenolic hydroxyl group (—OH) with, e.g., an acetyl group, or the like can also be used. In this case, the polymer (A) having the structural unit (III) may be synthesized by, for example: polymerizing the monomer, and then subjecting a polymerization reaction product thus obtained to a hydrolytic condensation reaction in the presence of a base such as an amine.

Other Structural Unit

Examples of the other structural unit include a structural unit (hereinafter, may be also referred to as “structural unit (IV)”) including an alcoholic hydroxyl group; a structural unit (hereinafter, may be also referred to as “structural unit (V)”) including a lactone structure, a cyclic carbonate structure, a sultone structure, or a combination thereof; and the like. The polymer (A) may have one, or two or more types of the other structural unit.

Structural Unit (IV)

The structural unit (IV) is a structural unit including an alcoholic hydroxyl group. When the polymer (A) has the structural unit (IV), the sensitivity to exposure light, and the CDU performance resulting from the radiation-sensitive resin composition can be further improved.

Examples of the structural unit (IV) include structural units represented by the following formulae, and the like.

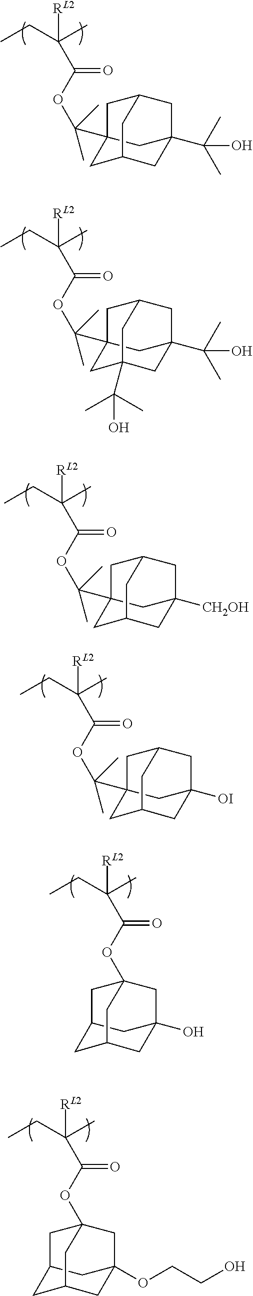

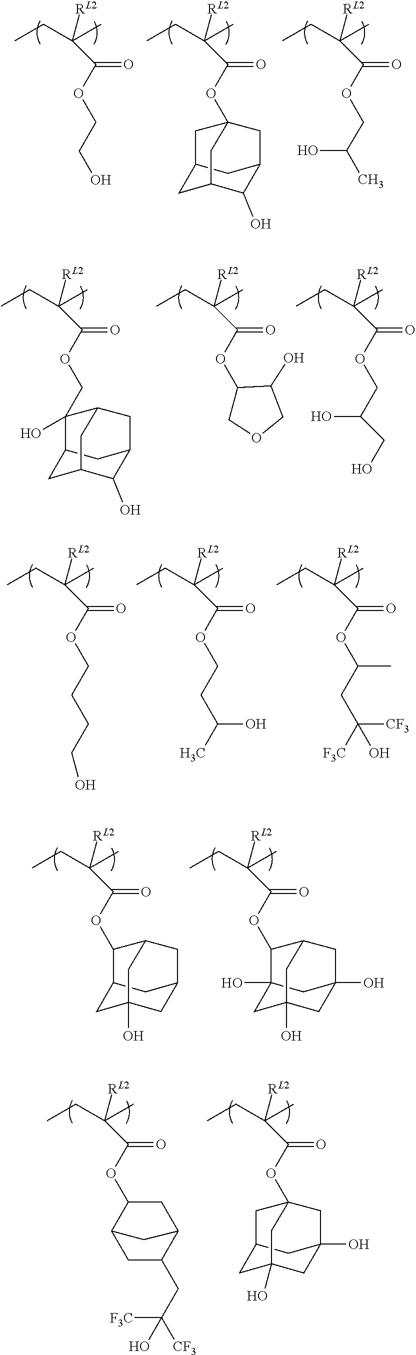

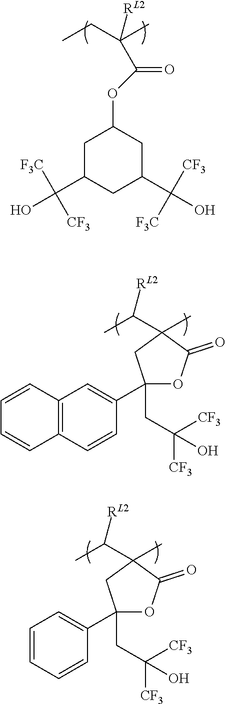

In the above formulae, R^{L2} represents a hydrogen atom, a fluorine atom, a methyl group, or a trifluoromethyl group.

In the case of the polymer (A) having the structural unit (IV), the lower limit of a proportion of the structural unit (IV) with respect to total structural units constituting the polymer (A) is preferably 0.5 mol %, more preferably 1 mol %, and still more preferably 2.5 mol %. The upper limit of the proportion is preferably 20 mol %, more preferably 15 mol %, and still more preferably 10 mol %.

Structural Unit (V)

The structural unit (V) is a structural unit including a lactone structure, a cyclic carbonate structure, a sultone structure, or a combination thereof. In the case of the polymer (A) having the structural unit (V), the CDU performance of a resist pattern formed from the radiation-sensitive resin composition can be further improved.

Examples of the structural unit (V) include structural units represented by the following formulae, and the like.

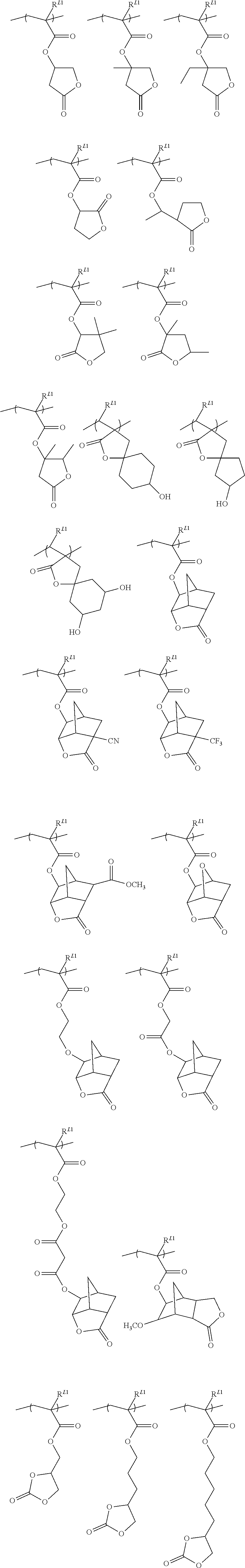

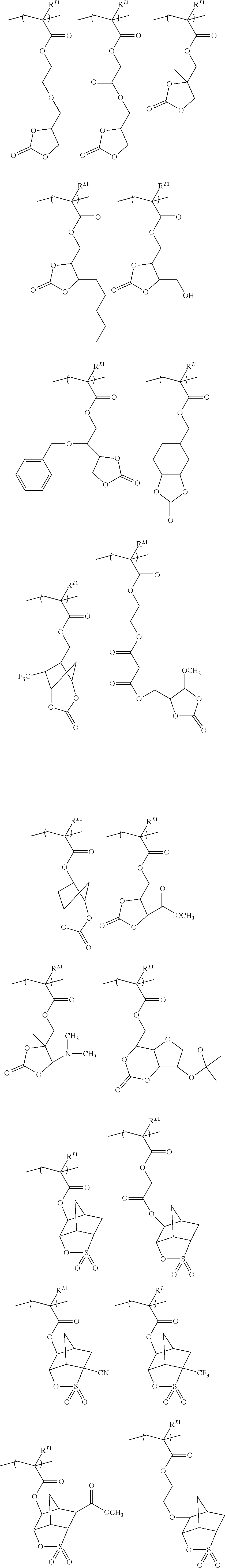

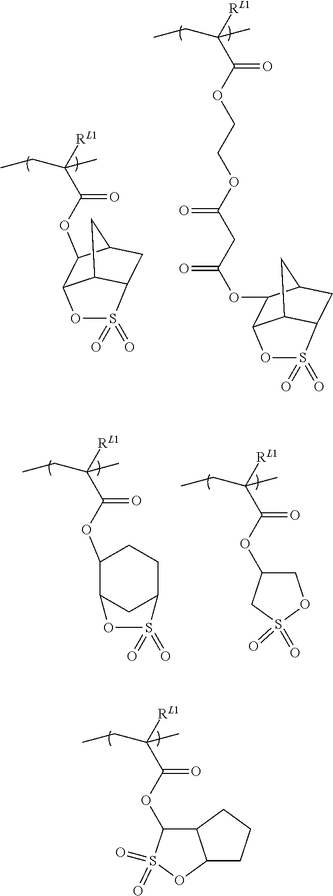

In the above formulae, R^{L1} represents a hydrogen atom, a fluorine atom, a methyl group, or a trifluoromethyl group.

The structural unit (V) is preferably a structural unit including a lactone structure or a cyclic carbonate structure.

In the case of the polymer (A) having the structural unit (V), the lower limit of a proportion of the structural unit (V) with respect to total structural units constituting the polymer (A) is preferably 0.5 mol %, more preferably 1 mol %, and still more preferably 2.5 mol %. The upper limit of the proportion is preferably 20 mol %, more preferably 15 mol %, and still more preferably 10 mol %.

(B) Acid Generator

The acid generator (B) is a substance that generates an acid upon exposure. The exposure light may be exemplified by types of exposure light similar to those exemplified as the exposure light in the exposing step of the method of forming a resist pattern of the other embodiment of the present invention, described later, and the like. The acid thus generated upon exposure allows the acid-labile group included in the structural unit (II) in the polymer (A) or the like to be dissociated, thereby generating a carboxy group, whereby a difference in solubility of the resist film in the developer solution is generated between the light-exposed regions and the light-unexposed regions, and thus formation of the resist pattern is enabled.

Examples of the acid generated from the acid generator (B) include sulfonic acid, imidic acid, and the like.

The acid generator (B) may be contained in the radiation-sensitive resin composition either in the form of a compound which is not a polymer (hereinafter, may be also referred to as “(B) acid generating agent” or “acid generating agent (B)”) or in the form of an acid generator incorporated as a part of the polymer, or may be in both of these forms. The radiation-sensitive resin composition may contain one, or two or more types of the acid generator (B).

The acid generating agent (B) is exemplified by an onium salt compound, an N-sulfonyloxyimide compound, a sulfonimide compound, a halogen-containing compound, a diazoketone compound, and the like.

Examples of the onium salt compound include sulfonium salts, tetrahydrothiophenium salts, iodonium salts, phosphonium salts, diazonium salts, pyridinium salts, and the like.

Specific examples of the acid generating agent (B) include compounds disclosed in paragraphs [0080] to [0113] of Japanese Unexamined Patent Application, Publication No. 2009-134088, and the like.

Examples of the acid generating agent (B) which generates sulfonic acid upon exposure include a compound (hereinafter, may be also referred to as “(B) compound” or “compound (B)”) represented by the following formula (4), and the like.

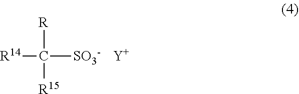

In the above formula (4), R¹⁴ represents a monovalent organic group having 1 to 30 carbon atoms; R¹⁵ represents a hydrogen atom, a fluorine atom, or a monovalent organic group having 1 to 10 carbon atoms; and Y⁺ represents a monovalent radiation-sensitive onium cation.

Examples of the monovalent organic group having 1 to 30 carbon atoms represented by R¹⁴ include groups similar to the monovalent organic groups exemplified as the monovalent organic group having 1 to 20 carbon atoms which may be represented by R¹, R², or R³ in the above formula (1), and the like.

Examples of the monovalent organic group having 1 to 10 carbon atoms which may be represented by R¹⁵ include groups similar to the monovalent organic groups exemplified as the monovalent organic group having 1 to 20 carbon atoms which may be represented by R¹, R², or R³ in the above formula (1), and the like.

The organic group represented by R¹⁴ is preferably a monovalent group including a ring structure having 5 or more ring atoms. Examples of the ring structure having 5 or more ring atoms include an alicyclic structure having 5 or more ring atoms, an aliphatic heterocyclic structure having 5 or more ring atoms, an aromatic carbocyclic structure having 5 or more ring atoms, an aromatic heterocyclic structure having 5 or more ring atoms, or a combination thereof.

Examples of the alicyclic structure having 5 or more ring atoms include: monocyclic saturated alicyclic structures such as a cyclopentane structure, a cyclohexane structure, a cycloheptane structure, a cyclooctane structure, a cyclononane structure, a cyclodecane structure, and a cyclododecane structure; monocyclic unsaturated alicyclic structures such as a cyclopentene structure, a cyclohexene structure, a cycloheptene structure, a cyclooctene structure, and a cyclodecene structure; polycyclic saturated alicyclic structures such as a norbornane structure, an adamantane structure, a tricyclodecane structure, and a tetracyclododecane structure; polycyclic unsaturated alicyclic structures such as a norbornene structure and a tricyclodecene structure; and the like.

Examples of the aliphatic heterocyclic structure having 5 or more ring atoms include: lactone structures such as a hexanolactone structure and a norbornanelactone structure; sultone structures such as a hexanosultone structure and a norbornanesultone structure; oxygen atom-containing heterocyclic structures such as an oxacycloheptane structure and an oxanorbornane structure; nitrogen atom-containing heterocyclic structures such as an azacyclohexane structure and a diazabicyclooctane structure; sulfur atom-containing heterocyclic structures such as a thiacyclohexane structure and a thianorbornane structure; and the like.

Examples of the aromatic carbocyclic structure having 5 or more ring atoms include a benzene structure, a naphthalene structure, a phenanthrene structure, an anthracene structure, and the like.

Examples of the aromatic heterocyclic structure having 5 or more ring atoms include: oxygen atom-containing heterocyclic structures such as a furan structure, a pyran structure, a benzofuran structure, and a benzopyran structure; nitrogen atom-containing heterocyclic structures such as a pyridine structure, a pyrimidine structure, and an indole structure; and the like.

The lower limit of the number of ring atoms contained in the ring structure is preferably 6, more preferably 8, still more preferably 9, and particularly preferably 10. The upper limit of the number of ring atoms is preferably 15, more preferably 14, still more preferably 13, and particularly preferably 12.

R¹⁵ represents preferably a fluorine atom.

Examples of the monovalent radiation-sensitive onium cation represented by Y⁺ include monovalent cations (hereinafter, may be also referred to as “cations (r-a) to (r-c)”) represented by the following formulae (r-a) to (r-c), and the like.

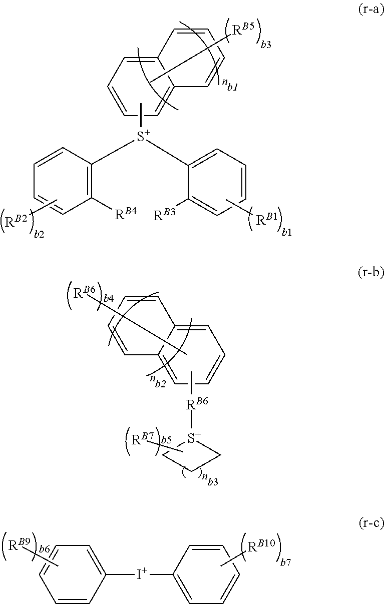

In the above formula (r-a), b1 is an integer of 0 to 4, wherein in a case in which b1 is 1, R^{B1} represents a halogen atom, a hydroxy group, a nitro group, or a monovalent organic group having 1 to 20 carbon atoms, and in a case in which b1 is no less than 2, a plurality of R^{B1}s are identical or different from each other, and each R^{B1} represents a halogen atom, a hydroxy group, a nitro group, or a monovalent organic group having 1 to 20 carbon atoms, or the plurality of R^{B1}s taken together represent a ring structure having 4 to 20 ring atoms together with the carbon chain to which the plurality of R^{B1}s bond; b2 is an integer of 0 to 4, wherein in a case in which b2 is 1, R^{B2} represents a halogen atom, a hydroxy group, a nitro group, or a monovalent organic group having 1 to 20 carbon atoms, and in a case in which b2 is no less than 2, a plurality of R^{B2}s are identical or different from each other, and each R^{B2} represents a halogen atom, a hydroxy group, a nitro group, or a monovalent organic group having 1 to 20 carbon atoms, or the plurality of R^{B2}s taken together represent a ring structure having 4 to 20 ring atoms together with the carbon chain to which the plurality of R^{B2}s bond; R^{B3} and R^{B4} each independently represent a hydrogen atom, a halogen atom, a hydroxy group, a nitro group, or a monovalent organic group having 1 to 20 carbon atoms, or R^{B3} and R^{B4} taken together represent a single bond; b3 is an integer of 0 to 11, wherein in a case in which b3 is 1, R^{B5} represents a halogen atom, a hydroxy group, a nitro group, or a monovalent organic group having 1 to 20 carbon atoms, and in a case in which b3 is no less than 2, a plurality of R^{B5}s are identical or different from each other, and each R^{B5} represents a halogen atom, a hydroxy group, a nitro group, or a monovalent organic group having 1 to 20 carbon atoms, or the plurality of R^{B5}s taken together represent a ring structure having 4 to 20 ring atoms together with the carbon chain to which the plurality of R^{B5}s bond; and n_{b1} is an integer of 0 to 3.

In the above formula (r-b), b4 is an integer of 0 to 9, wherein in a case in which b4 is 1, R^{B6} represents a halogen atom, a hydroxy group, a nitro group, or a monovalent organic group having 1 to 20 carbon atoms, and in a case in which b4 is no less than 2, a plurality of R^{B6}s are identical or different from each other, and each R^{B6} represents a halogen atom, a hydroxy group, a nitro group, or a monovalent organic group having 1 to 20 carbon atoms, or the plurality of R^{B6}s taken together represent a ring structure having 4 to 20 ring atoms together with the carbon chain to which the plurality of R^{B6}s groups bond; b5 is an integer of 0 to 10, wherein in a case in which b5 is 1, R^{B7} represents a halogen atom, a hydroxy group, a nitro group, or a monovalent organic group having 1 to 20 carbon atoms, and in a case in which b5 is no less than 2, a plurality of R^{B7}s are identical or different from each other, and each R^{B7} represents a halogen atom, a hydroxy group, a nitro group, or a monovalent organic group having 1 to 20 carbon atoms, or the plurality of R^{B7}s taken together represent a ring structure having 3 to 20 ring atoms together with the carbon chain to which the plurality of R^{B7}s bond; n_{b3} is an integer of 0 to 3; R^{B8} is a single bond or a divalent organic group having 1 to 20 carbon atoms; and n_{b2} is an integer of 0 to 2.

In the above formula (r-c), b6 is an integer of 0 to 5, wherein in a case in which b6 is 1, R^{B9} represents a halogen atom, a hydroxy group, a nitro group, or a monovalent organic group having 1 to 20 carbon atoms, and in a case in which b6 is no less than 2, a plurality of R^{B9}s are identical or different from each other, and each R^{B9} represents a halogen atom, a hydroxy group, a nitro group, or a monovalent organic group having 1 to 20 carbon atoms, or the plurality of R^{B9}s taken together represent a ring structure having 4 to 20 ring atoms together with the carbon chain to which the plurality of R^{B9}s bond; and b7 is an integer of 0 to 5, wherein in a case in which b7 is 1, R^{B10} represents a halogen atom, a hydroxy group, a nitro group, or a monovalent organic group having 1 to 20 carbon atoms, and in a case in which b7 is no less than 2, a plurality of R^{B10}s are identical or different from each other, and each R^{B10} represents a halogen atom, a hydroxy group, a nitro group, or a monovalent organic group having 1 to 20 carbon atoms, or these groups taken together represent a ring structure having 4 to 20 ring atoms together with the carbon chain to which the plurality of R^{B10}s bond.

Examples of the monovalent organic group having 1 to 20 carbon atoms which may be represented by R^{B1}, R^{B2}, R^{B3}, R^{B4}, R^{B5}, R^{B6}, R^{B7}, R^{B9}, or R^{B10} include groups similar to the groups exemplified as the monovalent organic group having 1 to 20 carbon atoms which may be represented by R¹, R², or R³ in the above formula (1), and the like.

Examples of the divalent organic group which may be represented by R^{B8} include groups obtained by removing one hydrogen atom from the groups exemplified as the monovalent organic group having 1 to 20 carbon atoms which may be represented by R¹, R², or R³ in the above formula (1), and the like.

R^{B3} and R^{B4} preferably each represent a hydrogen atom, or taken together represent a single bond.

b1 and b2 are each preferably 0 to 2, more preferably 0 or 1, and still more preferably 0. b3 is preferably 0 to 4, more preferably 0 to 2, and still more preferably 0 or 1. n_{b1} is preferably 0 or 1.

In the case in which b3 is no less than 1, R^{B5} is preferably a cyclohexyl group or a cyclohexylsulfonyl group.

The monovalent radiation-sensitive onium cation represented by Y⁺ is preferably the cation (r-a).

Examples of the cation (r-a) include cations (hereinafter, may be also referred to as “cations (r-a-1) to (r-a-7)”) represented by the following formulae (r-a-1) to (r-a-7), and the like.

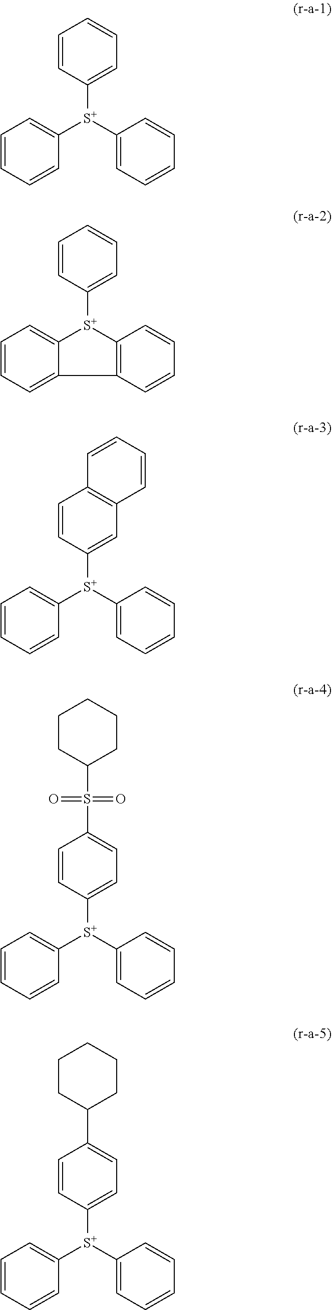 [SMILES: c1ccc([S+](c2ccccc2)c2ccccc2)cc1 ; c1ccc(-[s+]2c3ccccc3c3ccccc32)cc1 ; c1ccc([S+](c2ccccc2)c2ccc3ccccc3c2)cc1 ; O=S(=O)(c1ccc([S+](c2ccccc2)c2ccccc2)cc1)C1CCCCC1 ; c1ccc([S+](c2ccccc2)c2ccc(C3CCCCC3)cc2)cc1]

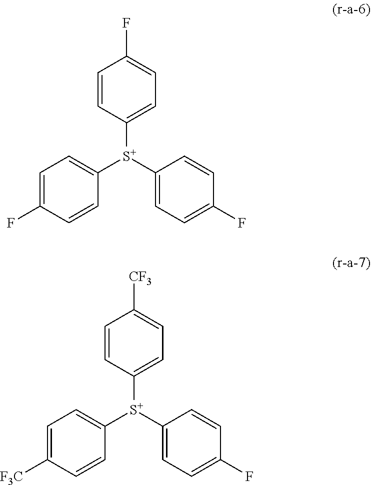 [SMILES: Fc1ccc([S+](c2ccc(F)cc2)c2ccc(F)cc2)cc1 ; Fc1ccc([S+](c2ccc(C(F)(F)F)cc2)c2ccc(C(F)(F)F)cc2)cc1]

Examples of the compound (B) include compounds (hereinafter, may be also referred to as “compounds (B1) to (B8)”) represented by the following formulae (4-1) to (4-8), and the like.

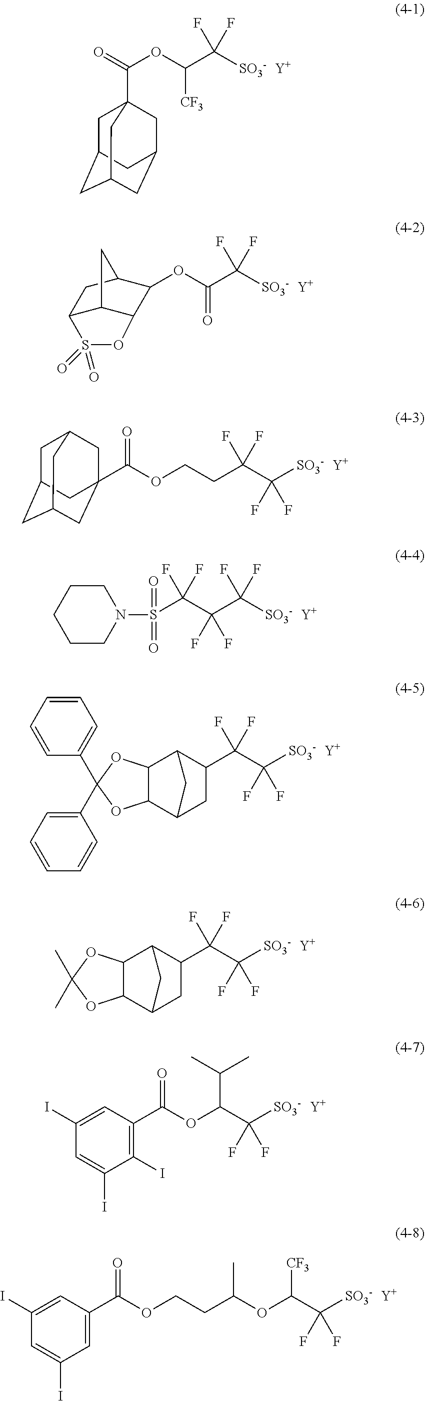

In the above formulae (4-1) to (4-8), Y⁺ is as defined in the above formula (4).

The lower limit of a content of the acid generating agent (B) in the radiation-sensitive resin composition with respect to 100 parts by mass of the polymer (A) is preferably 5 parts by mass, more preferably 10 parts by mass, and still more preferably 15 parts by mass. The upper limit of the content is preferably 60 parts by mass, more preferably 55 parts by mass, and still more preferably 50 parts by mass. When the content of the acid generating agent (B) falls within the above range, the sensitivity to exposure light, and the CDU performance and the resolution resulting from the radiation-sensitive resin composition can be further improved.

(C) Acid Diffusion Control Agent

The acid diffusion control agent (C) is able to control a diffusion phenomenon, in the resist film, of the acid generated from the acid generator (B), etc. upon exposure, thereby serving to inhibit unwanted chemical reactions in light-unexposed regions. When the radiation-sensitive resin composition contains the acid diffusion control agent (C), the sensitivity to exposure light, and the CDU performance and the resolution resulting from the radiation-sensitive resin composition can be further improved. The radiation-sensitive resin composition may contain one, or two or more types of the acid diffusion control agent (C).

The acid diffusion control agent (C) is exemplified by a nitrogen atom-containing compound, a photodegradable base that is photosensitized by exposure to generate a weak acid, and the like.

Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl)morpholine, 1-(tert-butoxycarbonyl)-4-hydroxypiperidine, and N-t-pentyloxycarbonyl-4-hydroxypiperidine; and the like. Of these, the amine compounds and the nitrogen-containing heterocyclic compounds are preferred, and trioctylamine or 1-(tert-butoxycarbonyl)-4-hydroxypiperidine is preferred.

The photodegradable base is exemplified by a compound containing an onium cation degraded by exposure, and an anion of a weak acid; and the like. The photodegradable base generates an acid in light-exposed regions and increases solubility or insolubility of the polymer (A) in a developer solution, and as a result roughness of a surface of the light-exposed regions after development is suppressed. On the other hand, the photodegradable base exerts a superior acid-capturing function by an anion at light-unexposed sites and serves as a quencher, and thus captures the acid diffused from the light-exposed sites. In other words, since the photodegradable base serves as a quencher only at the light-unexposed sites, the contrast resulting from a deprotection reaction is improved, and consequently the resolution can be improved.

Examples of the onium cation degraded by exposure include onium cations similar to those exemplified as the monovalent radiation-sensitive onium cation in the acid generating agent (B). Of these, a triphenylsulfonium cation or a phenyldibenzothiophenium cation is preferred.

Examples of the anion of a weak acid include anions represented by the following formulae, and the like.

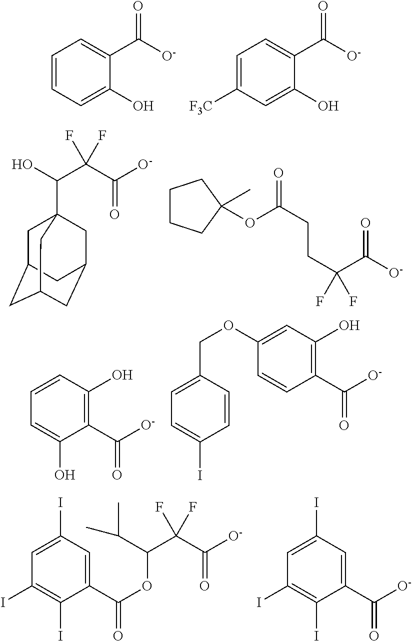

As the photodegradable base, a compound in which the onium cation degraded by exposure and the anion of a weak acid are appropriately combined can be used.

In the case of the radiation-sensitive resin composition containing the acid diffusion control agent (C), the lower limit of a proportion of the acid diffusion control agent (C) in the radiation-sensitive resin composition with respect to 100 mol % of the acid generating agent (B) is preferably 1 mol %, more preferably 5 mol %, and still more preferably 10 mol %. The upper limit of the proportion is preferably 100 mol %, more preferably 60 mol %, and still more preferably 50 mol %. When the proportion of the acid diffusion control agent (C) falls within the above range, the sensitivity to exposure light, and the CDU performance and the resolution resulting from the radiation-sensitive resin composition can be still further improved.

(D) Organic Solvent

The radiation-sensitive resin composition typically contains the organic solvent (D). The organic solvent (D) is not particularly limited as long as it is a solvent capable of dissolving or dispersing at least the polymer (A) and the acid generating agent (B), as well as the acid diffusion control agent (C) and the other optional component(s), which is/are contained as desired.

The organic solvent (D) is exemplified by an alcohol solvent, an ether solvent, a ketone solvent, an amide solvent, an ester solvent, a hydrocarbon solvent, and the like. The radiation-sensitive resin composition may contain one, or two or more types of the organic solvent (D).

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol 1-monomethyl ether; and the like.

Examples of the ether solvent include:

dialkyl ether solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone;

cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as n-butyl acetate and ethyl lactate;

lactone solvents such as y-butyrolactone and valerolactone;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

The organic solvent (D) is preferably the alcohol solvent and/or the ester solvent, more preferably the polyhydric alcohol partial ether solvent having 3 to 19 carbon atoms and/or the polyhydric alcohol partial ether carboxylate solvent, and still more preferably propylene glycol 1-monomethyl ether and/or propylene glycol monomethyl ether acetate.

In the case of the radiation-sensitive resin composition containing the organic solvent (D), the lower limit of a proportion of the organic solvent (D) contained with respect to total components contained in the radiation-sensitive resin composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

Other Optional Component(s)

The other optional component(s) is/are exemplified by a surfactant and the like. The radiation-sensitive resin composition may contain one, or two or more types each of the other optional component(s).

### Method of Forming Resist Pattern

The method of forming a resist pattern according to the other embodiment of the present invention includes: a step (hereinafter, may be also referred to as “applying step”) of applying a radiation-sensitive resin composition directly or indirectly on a substrate; a step (hereinafter, may be also referred to as “exposing step”) of exposing a resist film formed by the applying step; and a step (hereinafter, may be also referred to as “developing step”) of developing the resist film exposed.

According to the method of forming a resist film, due to using the radiation-sensitive resin composition of the one embodiment of the present invention as the radiation-sensitive resin composition in the applying step, formation of a resist pattern with favorable sensitivity to exposure light and superiority in terms of both the CDU performance and the resolution is enabled.

Each step included in the method of forming a resist pattern will be described below.

Applying Step

In this step, the radiation-sensitive resin composition is applied directly or indirectly on the substrate. By this step, the resist pattern is formed directly or indirectly on the substrate.

In this step, the radiation-sensitive resin composition of the one embodiment of the present invention, described above, is used as the radiation-sensitive resin composition.

The substrate is exemplified by a conventionally well-known substrate such as a silicon wafer, a wafer coated with silicon dioxide or aluminum, and the like. In addition, the case of the radiation-sensitive resin composition being applied indirectly on the substrate is exemplified by a case of the radiation-sensitive resin composition being applied on an antireflective film formed on the substrate, and the like. Examples of such an antireflective film include an organic or inorganic antireflective film disclosed in Japanese Examined Patent Application, Publication No. H6-12452, Japanese Unexamined Patent Application, Publication No. S59-93448, and the like.

An application procedure is exemplified by spin coating, cast coating, roll coating, and the like. After the application, prebaking (hereinafter, may be also referred to as “PB”) may be carried out as needed for evaporating the solvent remaining in the coating film. The lower limit of a PB temperature is preferably 60° C., and more preferably 80° C. The upper limit of the PB temperature is preferably 150° C., and more preferably 140° C. The lower limit of a PB time period is preferably 5 seconds, and more preferably 10 seconds. The upper limit of the PB time period is preferably 600 seconds, and more preferably 300 seconds. The lower limit of an average thickness of the resist film formed is preferably 10 nm, and more preferably 20 nm. The upper limit of the average thickness is preferably 1,000 nm, and more preferably 500 nm.

Exposing Step

In this step, the resist film formed by the applying step is exposed. This exposure is carried out by irradiation with an exposure light through a photomask (as the case may be, through a liquid immersion medium such as water). Examples of the exposure light include electromagnetic waves such as visible light rays, ultraviolet rays, far ultraviolet rays, extreme ultraviolet rays (EUV), X-rays and y-rays; charged particle rays such as electron beams and a-rays; and the like, which may be selected in accordance with a line width and the like of the intended pattern. Of these, far ultraviolet rays, EUV, or electron beams are preferred; an ArF excimer laser beam (wavelength: 193 nm), a KrF excimer laser beam (wavelength: 248 nm), EUV (wavelength: 13.5 mm), or an electron beam is more preferred; an KrF excimer laser beam, EUV, or an electron beam is still more preferred, and EUV or an electron beam is particularly preferred.

It is preferred that post exposure baking (hereinafter, may be also referred to as “PEB”) is carried out after the exposure to promote dissociation of the acid-labile group included in the polymer (A) and the like mediated by the acid generated from the acid generating (B), etc. upon the exposure in light-exposed regions of the resist film. This PEB enables an increase in a difference in solubility of the resist film in a developer solution between the light-exposed regions and light-unexposed regions. The lower limit of a PEB temperature is preferably 50° C., more preferably 80° C., and still more preferably 100° C. The upper limit of the PEB temperature is preferably 180° C., and more preferably 130° C. The lower limit of a PEB time period is preferably 5 seconds, more preferably 10 seconds, and still more preferably 30 seconds. The upper limit of the PEB time period is preferably 600 seconds, more preferably 300 seconds, and still more preferably 100 seconds.

Developing Step

In this step, the resist film exposed is developed. Accordingly, formation of a predetermined resist pattern is enabled. The development is typically followed by washing with a rinse agent such as water or an alcohol and then drying. The development procedure in the developing step may be carried out by either development with an alkali, or development with an organic solvent.

In the case of the development with an alkali, the developer solution for use in the development is exemplified by: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene; and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solution containing the organic solvent; and the like. An exemplary organic solvent includes one, or two or more types of the solvents exemplified as the organic solvent (D) of the radiation-sensitive resin composition of the one embodiment of the present invention, and the like. Of these, the ester solvent or the ketone solvent is preferred. The ester solvent is preferably an acetic acid ester solvent, and more preferably n-butyl acetate. The ketone solvent is preferably the chain ketone, and more preferably 2-heptanone. The lower limit of a content of the organic solvent in the developer solution is preferably 80% by mass, more preferably 90% by mass, still more preferably 95% by mass, and particularly preferably 99% by mass. Components other than the organic solvent in the developer solution are exemplified by water, silicone oil, and the like.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously dispensed onto the substrate, which is rotated at a constant speed, while scanning with a developer solution-dispensing nozzle at a constant speed; and the like.

The pattern to be formed according to the method of forming a resist pattern is exemplified by a line-and-space pattern, a hole pattern, and the like.

### Polymer

The polymer of the still another embodiment of the present invention is described as the polymer (A) in the radiation-sensitive resin composition of the one embodiment of the present invention, described above. The polymer of the still another embodiment of the present invention can be suitably used as a component of the radiation-sensitive resin composition of the one embodiment of the present invention.

### EXAMPLES

Hereinafter, the present invention is explained in detail by way of Examples, but the present invention is not in any way limited to these Examples. Measuring methods for various types of physical properties are shown below.

Weight Average Molecular Weight (Mw), Number Average Molecular Weight (Mn), and Dispersity Index (Mw/Mn)

The Mw and the Mn of the polymer (A) were measured in accordance with the conditions described in the above section “Method of Determining Mw and Mn.” The dispersity index (Mw/Mn) of the polymer was calculated from the measurement results of the Mw and the Mn.

Synthesis of Polymer (A)

Monomers (hereinafter, may be also referred to as “monomers (M-1) to (M-20)”) represented by the following formulae (M-1) to (M-20) were used in synthesis of the polymer (A). In the following Synthesis Examples, unless otherwise specified particularly, the term “parts by mass” means a value, provided that the total mass of the monomers used was 100 parts by mass, and the term “mol %” means a value, provided that the total mol number of the monomers used was 100 mol %.

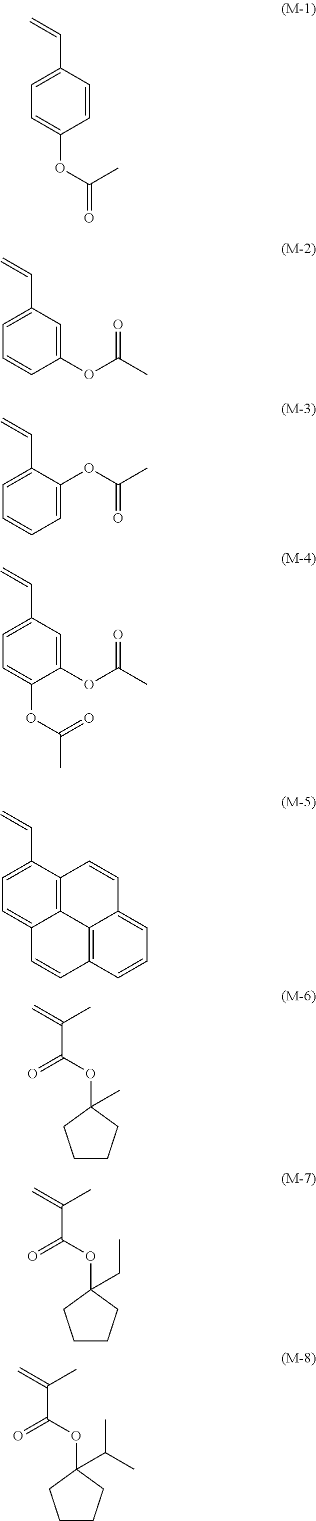

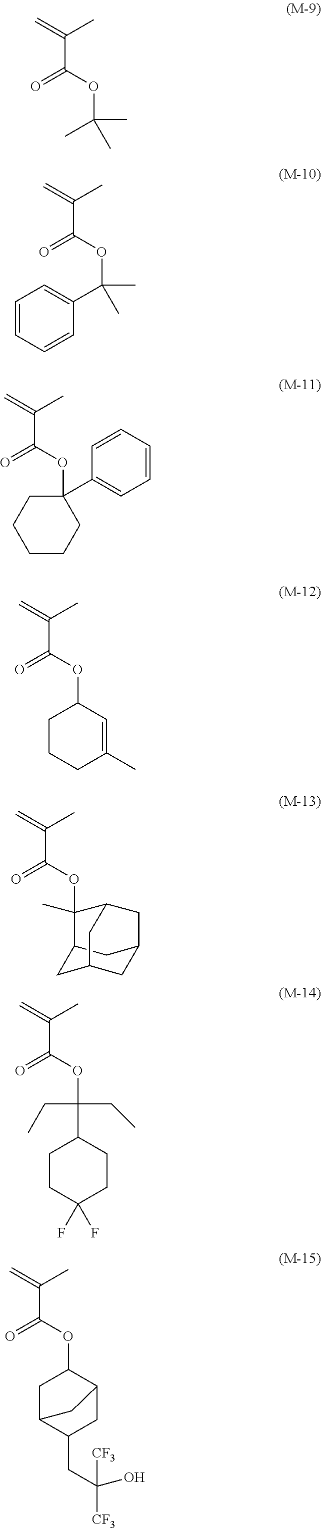

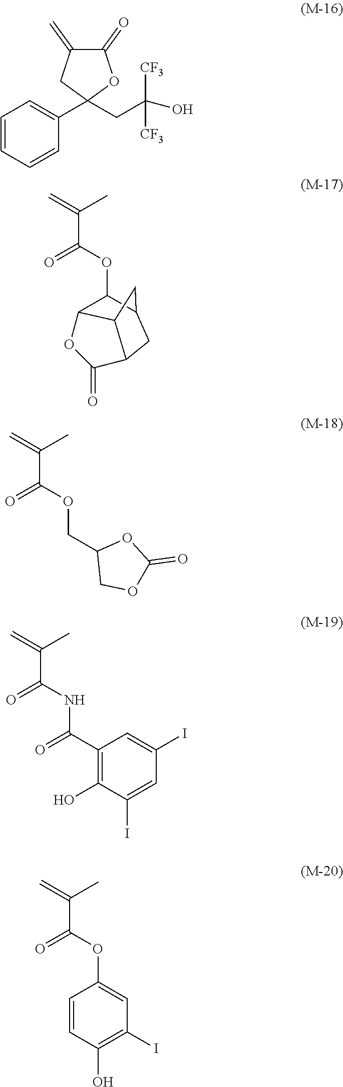

### Synthesis Example 1: Synthesis of Polymer (A-1)

The monomer (M-5), the monomer (M-6), and the monomer (M-1) were dissolved in propylene glycol 1-monomethyl ether (200 parts by mass) such that the molar ratio became 5/60/35. Next, a monomer solution was prepared by adding 6 mol % azobisisobutyronitrile (AIBN) as an initiator. Meanwhile, into an empty reaction vessel was charged propylene glycol 1-monomethyl ether (100 parts by mass), which was then heated to 85° C. with stirring.

Next, the monomer solution prepared as described above was added dropwise to the reaction vessel over 3 hours, then a thus resulting solution was further heated for 3 hours at 85° C., and a polymerization reaction was allowed to proceed for a total of 6 hours. After completion of the polymerization reaction, the polymerization solution was cooled to room temperature.

The polymerization solution thus cooled was charged into hexane (500 parts by mass with respect to the polymerization solution), and a thus precipitated white powder was filtered off. The white powder obtained by the filtration was washed twice with 100 parts by mass of hexane with respect to the polymerization solution, followed by filtering off and dissolution in propylene glycol 1-monomethyl ether (300 parts by mass). Next, methanol (500 parts by mass), triethylamine (50 parts by mass), and ultra-pure water (10 parts by mass) were added to a resulting solution, and a hydrolysis reaction was performed at 70° C. for 6 hours with stirring. After completion of the hydrolysis reaction, the remaining solvent was distilled away and a solid thus obtained was dissolved in acetone (100 parts by mass). The solution was added dropwise to 500 parts by mass of water to permit coagulation of the resin, and a solid thus obtained was filtered off. Drying at 50° C. for 12 hours gave a white powdery polymer (A-1). The Mw of the polymer (A-1) was 7,100, and the Mw/Mn was 1.52.

### Synthesis Examples 2 to 21: Synthesis of Polymers (A-2) to (A-20) and (a-1)

Polymers (A-2) to (A-20) and (a-1) were synthesized by a similar operation to that of Synthesis Example 1 except that monomers of the type and in the proportion shown in Table 1 below were used.

The type and the proportion of the monomer that gives each structural unit of each polymer obtained in Synthesis Examples 1 to 21, as well as the Mw and the Mw/Mn thereof, are shown in Table 1 below. It is to be noted that in Table 1, “-” indicates that the corresponding monomer was not used.

TABLE 1

| | | Monomer that gives | | Monomer that gives | | Monomer that gives | | Monomer that gives | | | |
|---|---|---|---|---|---|---|---|---|---|---|---|
| | | structural unit (I) | | structural unit (II) | | structural unit (III) | | other structural unit | | | |
| | (A) | | proportion | | proportion | | proportion | | proportion | | Mw/ |
| — | Polymer | type | (mol %) | type | (mol %) | type | (mol %) | type | (mol %) | Mw | Mn |
| Synthesis | A-1 | M-5 | 5 | M-6 | 60 | M-1 | 35 | — | — | 7,100 | 1.5 |
| Example 1 | | | | | | | | | | | |
| Synthesis | A-2 | M-5 | 10 | M-6 | 60 | M-1 | 30 | — | — | 7,200 | 1.6 |
| Example 2 | | | | | | | | | | | |
| Synthesis | A-3 | M-5 | 15 | M-6 | 60 | M-1 | 25 | — | — | 7,500 | 1.6 |
| Example 3 | | | | | | | | | | | |
| Synthesis | A-4 | M-5 | 5 | M-6 | 60 | M-1/M-2 | 30/5 | — | — | 7,000 | 1.5 |
| Example 4 | | | | | | | | | | | |
| Synthesis | A-5 | M-5 | 5 | M-6 | 60 | M-1/M-3 | 30/5 | — | — | 6,500 | 1.5 |
| Example 5 | | | | | | | | | | | |
| Synthesis | A-6 | M-5 | 5 | M-6 | 60 | M-1/M-4 | 30/5 | — | — | 6,900 | 1.6 |
| Example 6 | | | | | | | | | | | |
| Synthesis | A-7 | M-5 | 5 | M-7 | 60 | M-1 | 35 | — | — | 6,800 | 1.5 |
| Example 7 | | | | | | | | | | | |
| Synthesis | A-8 | M-5 | 5 | M-8 | 60 | M-1 | 35 | — | — | 6,700 | 1.5 |
| Example 8 | | | | | | | | | | | |
| Synthesis | A-9 | M-5 | 5 | M-9 | 60 | M-1 | 35 | — | — | 6,700 | 1.6 |
| Example 9 | | | | | | | | | | | |
| Synthesis | A-10 | M-5 | 5 | M-10 | 60 | M-1 | 35 | — | — | 6,600 | 1.6 |
| Example 10 | | | | | | | | | | | |
| Synthesis | A-11 | M-5 | 5 | M-11 | 60 | M-1 | 35 | — | — | 7,000 | 1.6 |
| Example 11 | | | | | | | | | | | |
| Synthesis | A-12 | M-5 | 5 | M-12 | 60 | M-1 | 35 | — | — | 7,500 | 1.6 |
| Example 12 | | | | | | | | | | | |
| Synthesis | A-13 | M-5 | 5 | M-13 | 60 | M-1 | 35 | — | — | 6,300 | 1.5 |
| Example 13 | | | | | | | | | | | |
| Synthesis | A-14 | M-5 | 5 | M-14 | 60 | M-1 | 35 | — | — | 6,000 | 1.6 |
| Example 14 | | | | | | | | | | | |
| Synthesis | A-15 | M-5 | 5 | M-6 | 60 | M-1 | 30 | M-15 | 5 | 6,500 | 1.6 |
| Example 15 | | | | | | | | | | | |
| Synthesis | A-16 | M-5 | 5 | M-6 | 60 | M-1 | 30 | M-16 | 5 | 6,400 | 1.6 |
| Example 16 | | | | | | | | | | | |
| Synthesis | A-17 | M-5 | 5 | M-6 | 60 | M-1 | 30 | M-17 | 5 | 7,100 | 1.5 |
| Example 17 | | | | | | | | | | | |
| Synthesis | A-18 | M-5 | 5 | M-6 | 60 | M-1 | 30 | M-18 | 5 | 7,200 | 1.6 |
| Example 18 | | | | | | | | | | | |
| Synthesis | A-19 | M-5 | 5 | M-6 | 60 | M-1/M-19 | 30/5 | — | — | 7,100 | 1.5 |
| Example 19 | | | | | | | | | | | |
| Synthesis | A-20 | M-5 | 5 | M-6 | 60 | M-1/M-20 | 30/5 | — | — | 7,400 | 1.6 |
| Example 20 | | | | | | | | | | | |
| Synthesis | a-1 | — | — | M-6 | 60 | M-1 | 40 | — | — | 7,600 | 1.6 |
| Example 21 | | | | | | | | | | | |

### Preparation of Radiation-Sensitive Resin Composition

The acid generating agent (B), the acid diffusion control agent (C), and the organic solvent (D) used in preparing each radiation-sensitive resin composition are shown below. Unless otherwise specified particularly, the term “parts by mass” means a value, provided that the mass of the polymer (A) used was 100 parts by mass, and the term “mol %” means a value, provided that the mol number of the acid generating agent (B) used was 100 mol %.

(B) Acid Generating Agent Compounds (hereinafter, may be also referred to as “acid generating agents (B-1) to (B-8)”) represented by the following formulae (B-1) to (B-8) were used as the acid generating agent (B).

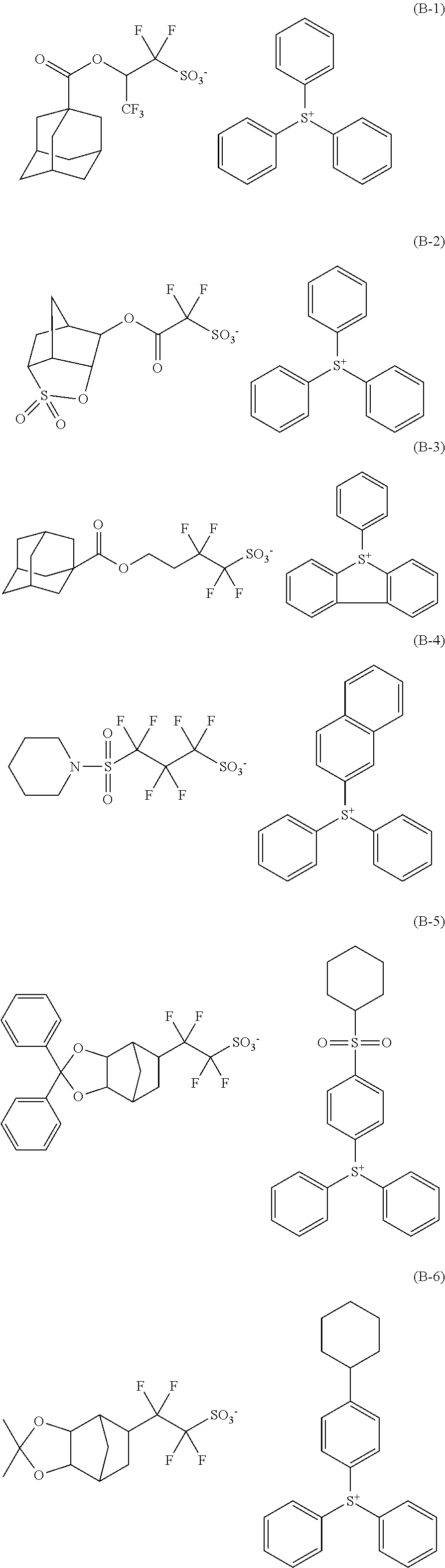

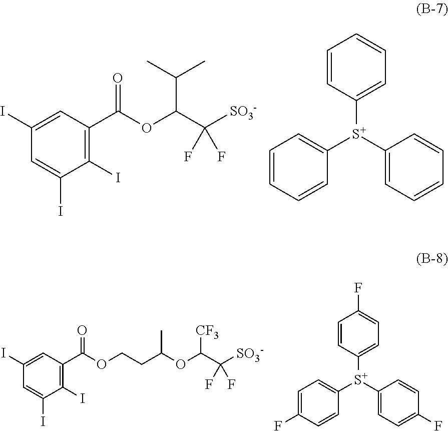

(C) Acid Diffusion Control Agent

Compounds (hereinafter, may be also referred to as “acid diffusion control agents (C-1) to (C-8)”) represented by the following formulae (C-1) to (C-8) were used as the acid diffusion control agent (C).

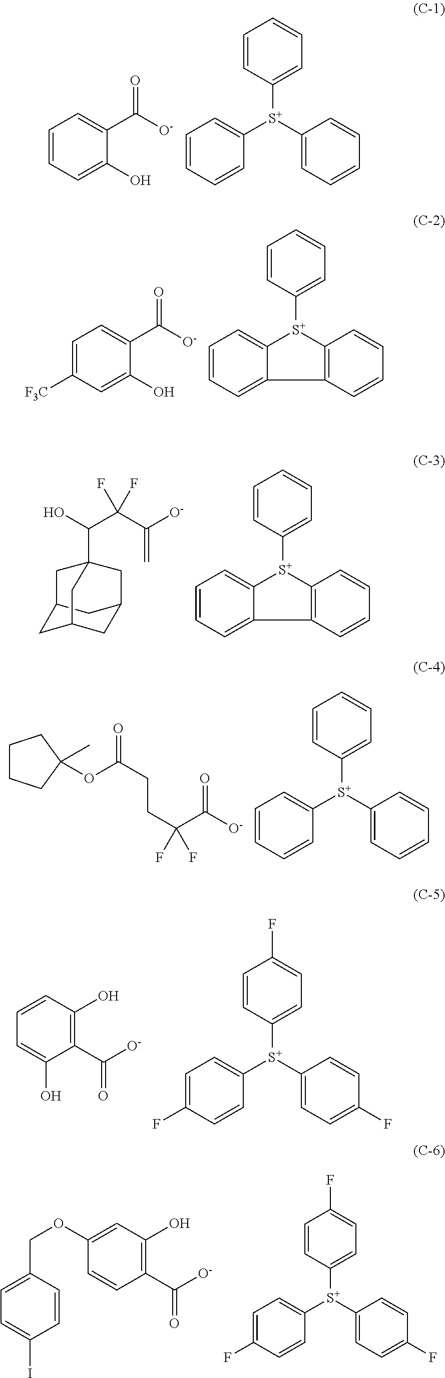

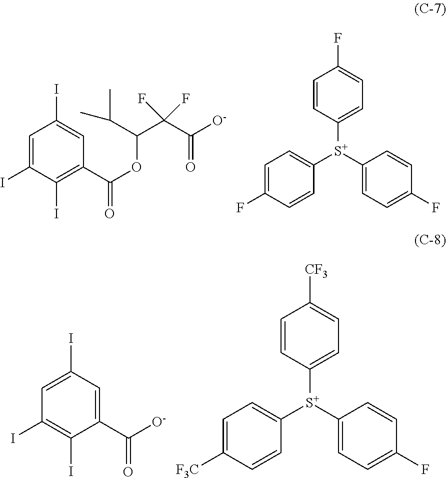 [SMILES: CC(C)C(OC(=O)c1cc(I)cc(I)c1I)C(F)(F)C(=O)[O-] ; Fc1ccc([S+](c2ccc(F)cc2)c2ccc(F)cc2)cc1 ; O=C([O-])c1cc(I)cc(I)c1I ; Fc1ccc([S+](c2ccc(C(F)(F)F)cc2)c2ccc(C(F)(F)F)cc2)cc1]

(D) Organic Solvent

(D-1) and (D-2) below were used as the organic solvent (D).

(D-1): propylene glycol monomethyl ether acetate

(D-2): propylene glycol 1-monomethyl ether

### Example 1: Preparation of Radiation-Sensitive Resin Composition (R-1)

A radiation-sensitive resin composition (R-1) was prepared by: mixing 100 parts by mass of (A-1) as the polymer (A), 20 parts by mass of (B-1) as the acid generating agent (B), 45 mol % of (C-1) with respect to (B-1) as the acid diffusion control agent (C), and 4,800 parts by mass of (D-1) and 2,000 parts by mass of (D-2) as the organic solvent (D), and filtering a resulting mixture through a membrane filter having a pore size of 0.20 μm.

### Examples 2 to 28 and Comparative Example 1: Preparation of Radiation-Sensitive Resin Compositions (R-2) to (R-36) and (CR-1)

Radiation-sensitive resin compositions (R-2) to (R-36) and (CR-1) were prepared in a similar manner to Example 1, except that for each component, the type and content shown in Table 2 below were used.

TABLE 2

| | | | | | | (C) Acid diffusion control | | | |
|---|---|---|---|---|---|---|---|---|---|
| | Radiation- | (A) Polymer | | (B) Acid generating agent | | agent | | (D) Organic solvent | |
| | sensitive resin | | content | | content | | proportion | | content |
| — | composition | type | (parts by mass) | type | (parts by mass) | type | (mol %) | type | (parts by mass) |
| Example 1 | R-1 | A-1 | 100 | B-1 | 20 | C-1 | 45 | D-1/D-2 | 4,800/2,000 |
| Example 2 | R-2 | A-2 | 100 | B-1 | 20 | C-1 | 45 | D-1/D-2 | 4,800/2,000 |
| Example 3 | R-3 | A-3 | 100 | B-1 | 20 | C-1 | 45 | D-1/D-2 | 4,800/2,000 |
| Example 4 | R-4 | A-4 | 100 | B-1 | 20 | C-1 | 45 | D-1/D-2 | 4,800/2,000 |
| Example 5 | R-5 | A-5 | 100 | B-1 | 20 | C-1 | 45 | D-1/D-2 | 4,800/2,000 |
| Example 6 | R-6 | A-6 | 100 | B-1 | 20 | C-1 | 45 | D-1/D-2 | 4,800/2,000 |
| Example 7 | R-7 | A-7 | 100 | B-1 | 20 | C-1 | 45 | D-1/D-2 | 4,800/2,000 |
| Example 8 | R-8 | A-8 | 100 | B-1 | 20 | C-1 | 45 | D-1/D-2 | 4,800/2,000 |
| Example 9 | R-9 | A-9 | 100 | B-1 | 20 | C-1 | 45 | D-1/D-2 | 4,800/2,000 |
| Example 10 | R-10 | A-10 | 100 | B-1 | 20 | C-1 | 45 | D-1/D-2 | 4,800/2,000 |
| Example 11 | R-11 | A-11 | 100 | B-1 | 20 | C-1 | 45 | D-1/D-2 | 4,800/2,000 |
| Example 12 | R-12 | A-12 | 100 | B-1 | 20 | C-1 | 45 | D-1/D-2 | 4,800/2,000 |
| Example 13 | R-13 | A-13 | 100 | B-1 | 20 | C-1 | 45 | D-1/D-2 | 4,800/2,000 |
| Example 14 | R-14 | A-14 | 100 | B-1 | 20 | C-1 | 45 | D-1/D-2 | 4,800/2,000 |
| Example 15 | R-15 | A-15 | 100 | B-1 | 20 | C-1 | 45 | D-1/D-2 | 4,800/2,000 |
| Example 16 | R-16 | A-16 | 100 | B-1 | 20 | C-1 | 45 | D-1/D-2 | 4,800/2,000 |
| Example 17 | R-17 | A-17 | 100 | B-1 | 20 | C-1 | 45 | D-1/D-2 | 4,800/2,000 |
| Example 18 | R-18 | A-18 | 100 | B-1 | 20 | C-1 | 45 | D-1/D-2 | 4,800/2,000 |
| Example 19 | R-19 | A-19 | 100 | B-1 | 20 | C-1 | 45 | D-1/D-2 | 4,800/2,000 |
| Example 20 | R-20 | A-20 | 100 | B-1 | 20 | C-1 | 45 | D-1/D-2 | 4,800/2,000 |
| Example 21 | R-21 | A-1 | 100 | B-1 | 30 | C-1 | 45 | D-1/D-2 | 4,800/2,000 |
| Example 22 | R-22 | A-1 | 100 | B-1 | 40 | C-1 | 45 | D-1/D-2 | 4,800/2,000 |
| Example 23 | R-23 | A-1 | 100 | B-2 | 20 | C-1 | 45 | D-1/D-2 | 4,800/2,000 |
| Example 24 | R-24 | A-1 | 100 | B-3 | 20 | C-1 | 45 | D-1/D-2 | 4,800/2,000 |
| Example 25 | R-25 | A-1 | 100 | B-4 | 20 | C-1 | 45 | D-1/D-2 | 4,800/2,000 |
| Example 26 | R-26 | A-1 | 100 | B-5 | 20 | C-1 | 45 | D-1/D-2 | 4,800/2,000 |
| Example 27 | R-27 | A-1 | 100 | B-6 | 20 | C-1 | 45 | D-1/D-2 | 4,800/2,000 |
| Example 28 | R-28 | A-1 | 100 | B-7 | 20 | C-1 | 45 | D-1/D-2 | 4,800/2,000 |
| Example 29 | R-29 | A-1 | 100 | B-8 | 20 | C-1 | 45 | D-1/D-2 | 4,800/2,000 |
| Example 30 | R-30 | A-1 | 100 | B-1 | 20 | C-2 | 45 | D-1/D-2 | 4,800/2,000 |
| Example 31 | R-31 | A-1 | 100 | B-1 | 20 | C-3 | 45 | D-1/D-2 | 4,800/2,000 |
| Example 32 | R-32 | A-1 | 100 | B-1 | 20 | C-4 | 45 | D-1/D-2 | 4,800/2,000 |
| Example 33 | R-33 | A-1 | 100 | B-1 | 20 | C-5 | 45 | D-1/D-2 | 4,800/2,000 |
| Example 34 | R-34 | A-1 | 100 | B-1 | 20 | C-6 | 45 | D-1/D-2 | 4,800/2,000 |
| Example 35 | R-35 | A-1 | 100 | B-1 | 20 | C-7 | 45 | D-1/D-2 | 4,800/2,000 |
| Example 36 | R-36 | A-1 | 100 | B-1 | 20 | C-8 | 45 | D-1/D-2 | 4,800/2,000 |
| Comparative | CR-1 | a-1 | 100 | B-1 | 20 | C-1 | 45 | D-1/D-2 | 4,800/2,000 |
| Example 1 | | | | | | | | | |

### Resist Pattern Formation

Using a spin coater (“CLEAN TRACK ACT 12,” available from Tokyo Electron Limited), the radiation-sensitive resin compositions prepared as described above were each applied on an underlayer film (“AL412,” available from Brewer Science, Inc.) formed on a 12-inch silicon wafer, the underlayer film having an average thickness of 20 nm. Prebaking (PB) was conducted at 130° C. for 60 seconds, and then, by cooling at 23° C. for 30 seconds, a resist film having an average thickness of 50 nm was formed. Next, the resist film was exposed using an EUV scanner (model “NXE3300,” available from ASML Co.) with NA of 0.33 under an illumination condition of Conventional s=0.89, and with a mask of imecDEFECT32FFR02. After the exposure, the resist film was subjected to post-exposure baking (PEB) at 130° C. for 60 seconds. Thereafter, the resist film was developed at 23° C. for 30 seconds by using a 2.38% by mass aqueous TMAH solution to form a positive-tone contact hole pattern (25 nm diameter, 50 nm pitch).

### Evaluations

With regard to each resist pattern formed as described above, the sensitivity, the CDU performance, and the resolution were evaluated in accordance with the following methods. A scanning electron microscope (“CG-4100,” available from Hitachi High-Technologies Corporation) was used for line-width measurement of the resist patterns. The results of the evaluations are shown in Table 3 below.

Sensitivity

An exposure dose at which a contact hole pattern with a diameter of 25 nm was formed in the aforementioned resist pattern formation was defined as an optimum exposure dose, and this optimum exposure dose was adopted as Eop (mJ/cm²). The sensitivity was evaluated to be: “favorable” in a case of the Eop being no greater than 50 mJ/cm²; and “unfavorable” in a case of the Eop being greater than 50 mJ/cm².

CDU Performance

Each resist pattern formed as described above was observed from above using the scanning electron microscope. The diameter of the contact hole pattern was measured at 800 arbitrary sites, and then a 3 Sigma value was determined from distribution of the measurement values and defined as “CDU” (units: nm). The CDU value being smaller indicates a more favorable CDU performance, revealing less variance of the hole diameters in greater ranges. The CDU performance was evaluated to be: “favorable” in a case of being no greater than 4.3 nm; and “unfavorable” in a case of being greater than 4.3 nm.

Resolution

A diameter of a minimum contact hole pattern being resolved when the exposure dose was changed in the resist pattern formation was measured, and the measurement value was defined as the “resolution” (units: nm). The resolution value being smaller indicates a more favorable resolution. The resolution was evaluated to be: “favorable” in a case being no greater than 24.5 nm; and “unfavorable” in a case of being greater than 24.5 nm.

TABLE 3

| — | Radiation- sensitive resin composition | Eop (mJ/cm²) | CDU (nm) | Resolution (nm) |
|---|---|---|---|---|
| Example 1 | R-1 | 48 | 4.2 | 22.5 |
| Example 2 | R-2 | 49 | 4.0 | 20.5 |
| Example 3 | R-3 | 50 | 3.8 | 18.5 |
| Example 4 | R-4 | 49 | 4.1 | 21.5 |
| Example 5 | R-5 | 49 | 4.1 | 20.5 |
| Example 6 | R-6 | 46 | 4.1 | 20.5 |
| Example 7 | R-7 | 48 | 4.1 | 21.5 |
| Example 8 | R-8 | 49 | 4.0 | 18.5 |
| Example 9 | R-9 | 47 | 4.3 | 24.5 |
| Example 10 | R-10 | 48 | 4.1 | 19.5 |
| Example 11 | R-11 | 49 | 4.1 | 23.5 |
| Example 12 | R-12 | 48 | 4.0 | 20.5 |
| Example 13 | R-13 | 50 | 4.4 | 24.5 |
| Example 14 | R-14 | 48 | 3.9 | 19.5 |
| Example 15 | R-15 | 47 | 4.1 | 23.5 |
| Example 16 | R-16 | 47 | 4.1 | 20.5 |
| Example 17 | R-17 | 48 | 4.2 | 23.5 |
| Example 18 | R-18 | 48 | 4.1 | 23.5 |
| Example 19 | R-19 | 46 | 4.0 | 23.0 |
| Example 20 | R-20 | 48 | 4.0 | 22.0 |
| Example 21 | R-21 | 49 | 4.2 | 19.5 |
| Example 22 | R-22 | 50 | 4.3 | 20.5 |
| Example 23 | R-23 | 47 | 4.1 | 21.5 |
| Example 24 | R-24 | 46 | 4.0 | 19.5 |
| Example 25 | R-25 | 49 | 4.3 | 20.5 |
| Example 26 | R-26 | 48 | 4.3 | 24.5 |
| Example 27 | R-27 | 47 | 4.3 | 23.5 |
| Example 28 | R-28 | 46 | 3.9 | 20.0 |
| Example 29 | R-29 | 44 | 3.8 | 19.0 |
| Example 30 | R-30 | 47 | 4.1 | 18.5 |
| Example 31 | R-31 | 46 | 4.3 | 21.5 |
| Example 32 | R-32 | 45 | 4.3 | 20.5 |
| Example 33 | R-33 | 44 | 4.1 | 20.0 |
| Example 34 | R-34 | 43 | 4.0 | 18.5 |
| Example 35 | R-35 | 41 | 3.9 | 18.0 |
| Example 36 | R-36 | 42 | 3.9 | 18.0 |
| Comparative | CR-1 | 53 | 4.6 | 25.5 |
| Example 1 | | | | |

As is clear from the results shown in Table 3, with regard to the radiation-sensitive resin compositions of the Examples, each of the sensitivity, the CDU performance, and the resolution were favorable when compared to those of the radiation-sensitive resin compositions of the Comparative Examples.

The radiation-sensitive resin composition and the method of forming a resist pattern of the embodiments of the present invention enable a resist pattern to be formed with favorable sensitivity to exposure light and superiority in terms of the CDU performance and the resolution. The polymer of the still another embodiment of the present invention can be suitably used as a component of the radiation-sensitive resin composition of the one embodiment of the present invention. Therefore, these can be suitably used for working processes of semiconductor devices, and the like, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a polymer comprising:
a first structural unit represented by formula (1); and
a second structural unit derived from a (meth)acrylic acid ester comprising an acid-labile group; and
a radiation-sensitive acid generator, 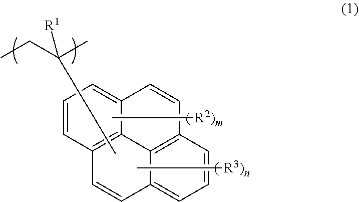
wherein, in the formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.

2. The radiation-sensitive resin composition according to claim 1, wherein R¹ in the formula (1) represents a hydrogen atom.

3. The radiation-sensitive resin composition according to claim 1, wherein a proportion of the first structural unit with respect to total structural units constituting the polymer is no less than 1 mol % and no greater than 20 mol %.

4. A method of forming a resist pattern, the method comprising:
applying a radiation-sensitive resin composition directly or indirectly on a substrate;
exposing a resist film formed by the applying; and
developing the resist film exposed, wherein
the radiation-sensitive resin composition comprises:
a polymer comprising:
a first structural unit represented by formula (1); and
a second structural unit derived from a (meth)acrylic acid ester
comprising an acid-labile group; and
a radiation-sensitive acid generator, 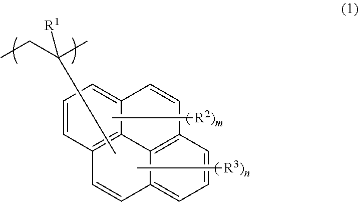
wherein, in the formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.

5. A polymer comprising:
a first structural unit represented by formula (1); and
a second structural unit derived from a (meth)acrylic acid ester comprising an acid-labile group, 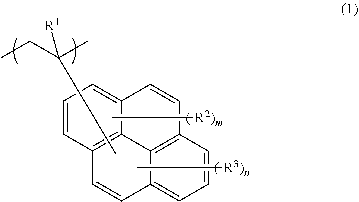
wherein, in the formula (1), R¹ represents a hydrogen atom, a halogen atom, or a monovalent organic group having 1 to 20 carbon atoms; R² and R³ each independently represent a halogen atom, a hydroxy group, a nitro group, or a monovalent organic group having 1 to 20 carbon atoms; m is an integer of 0 to 9; and n is an integer of 0 to 9, wherein a sum of m and n is no greater than 9, in a case in which m is no less than 2, a plurality of R²s are identical or different from each other, and in a case in which n is no less than 2, a plurality of R³s are identical or different from each other.
